(19) United States
(12) Patent Application Publication
(10) Pub. No.: US 2025/0275386 A1
(43) Pub. Date: Aug. 28, 2025

(54) Display Device

(71) Applicant: LG Display Co., Ltd., Seoul (KR)

(72) Inventor: Dongmin Lee, Paju-si (KR)

(21) Appl. No.: 19/012,734

(22) Filed: Jan. 7, 2025

(30) Foreign Application Priority Data
Feb. 26, 2024 (KR) 10-2024-0027402

(51) Int. Cl. H10K 59/126; H10K 59/80

(52) U.S. Cl. CPC H10K 59/126; H10K 59/879

(57) ABSTRACT

According to an aspect of the present disclosure, a display device includes a first substrate; a first light shielding layer disposed on the first substrate; a transistor disposed on the first light shielding layer; a second light shielding layer disposed on the transistor; and a light emitting diode which is disposed on the second light shielding layer and is electrically connected to the transistor, and each of the first light shielding layer and the second light shielding layer includes a first insulating layer; a plurality of particles disposed on the first insulating layer; and a second insulating layer disposed on the first insulating layer and the plurality of particles.

### CROSS-REFERENCE TO RELATED APPLICATION

This application claims the priority of Republic of Korea Patent Application No. 10-2024-0027402 filed on Feb. 26, 2024, which is hereby incorporated by reference in its entirety.

### BACKGROUND

### Field

The present disclosure related to a display device, and more particularly, to a display device which improves a reliability of a transistor.

### Description of the Related Art

As it enters the information era, a field of a display device which visually expresses electrical information signals has been rapidly developed and studies are continued to improve performances of various display devices, such as a thin-thickness, a light weight, and low power consumption.

A representative display device may include a liquid crystal display device (LCD), a field emission display device (FED), an electro-wetting display device (EWD), and an organic light emitting display device (OLED).

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

### SUMMARY

An object to be achieved by an exemplary embodiment of the present disclosure is to provide a display device which improves a reliability of a transistor by shielding light in various paths which is guided to a transistor.

An object to be achieved by another exemplary embodiment of the present disclosure is to provide a display device which has a uni-material in which a light shielding layer and an insulating layer are unified by configuring one component to perform both a light shielding function and an insulating function.

Objects of the present disclosure are not limited to the above-mentioned objects, and other objects, which are not mentioned above, can be clearly understood by those skilled in the art from the following descriptions.

According to an embodiment of the present disclosure, a display device includes a first substrate; a first light shielding layer disposed on the first substrate; a transistor disposed on the first light shielding layer; a second light shielding layer disposed on the transistor; and a light emitting diode which is disposed on the second light shielding layer and is electrically connected to the transistor, and each of the first light shielding layer and the second light shielding layer includes a first insulating layer; a plurality of particles disposed on the first insulating layer; and a second insulating layer disposed on the first insulating layer and the plurality of particles.

Other detailed matters of the exemplary embodiments are included in the detailed description and the drawings.

According to the exemplary embodiment of the present disclosure, the display device is configured such that an insulating layer disposed above and below a transistor has a light shielding characteristic to shield light which is guided to a transistor.

According to the exemplary embodiment of the present disclosure, the light shielding layer performs both a light shielding function and an insulating function so that a configuration of a display device is simplified.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a display device according to an exemplary embodiment of the present disclosure;

FIG. 2 is a cross-sectional view taken along the line II-II′ of FIG. 1 according to an exemplary embodiment of the present disclosure;

FIG. 3 is an enlarged cross-sectional view of a first light shielding layer of a display device according to an exemplary embodiment of the present disclosure;

FIG. 4 is a cross-sectional view of a display device according to another exemplary embodiment of the present disclosure;

FIG. 5 is a cross-sectional view of a display device according to still another exemplary embodiment of the present disclosure;

FIG. 6 is a cross-sectional view of a display device according to still another exemplary embodiment of the present disclosure;

FIG. 7 is a cross-sectional view of a display device according to still another exemplary embodiment of the present disclosure;

FIG. 8 is a cross-sectional view of a display device according to still another exemplary embodiment of the present disclosure;

FIG. 9 is a cross-sectional view of a display device according to still another exemplary embodiment of the present disclosure;

FIG. 10 is a cross-sectional view of a display device according to still another exemplary embodiment of the present disclosure;

FIG. 11 is a cross-sectional view of a display device according to still another exemplary embodiment of the present disclosure; and

FIG. 12 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘comprising’ used herein are generally intended to allow other components to be added unless the terms are used with the term ‘only’. Any references to singular may include plural unless expressly stated otherwise.

Components are interpreted to include an ordinary error range even if not expressly stated.

When the position relation between two parts is described using the terms such as ‘on’, ‘above’, ‘below’, ‘next’, one or more parts may be positioned between the two parts unless the terms are used with the term ‘immediately’ or ‘directly’.

When an element or layer is disposed “on” another element or layer, another layer or another element may be interposed therebetween, or it may be directly on the other element or layer.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Same reference numerals generally denote same elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

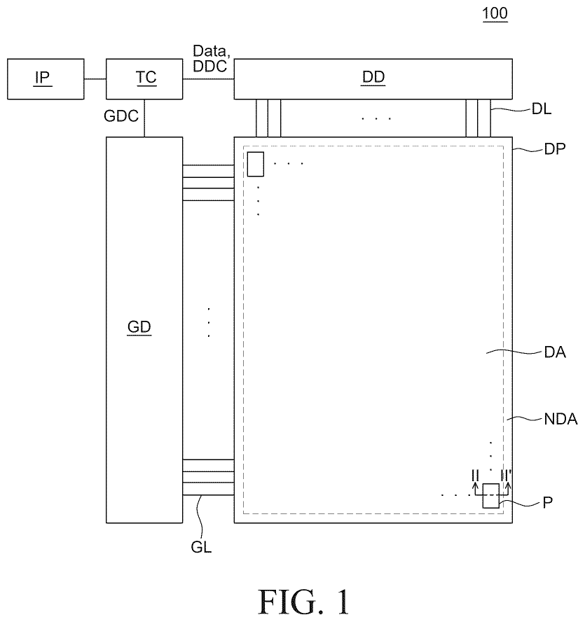

FIG. 1 is a block diagram of a display device according to an exemplary embodiment of the present disclosure.

Referring to FIG. 1, a display device 100 according to an exemplary embodiment of the present disclosure may include an image processor IP, a timing controller TC, a data driver DD, a gate driver GD, and a display panel DP.

At this time, the image processor IP may output a data signal and a data enable signal supplied from the outside. The image processor IP may output one or more of a vertical synchronization signal, a horizontal synchronization signal, and a clock signal in addition to the data enable signal.

The timing controller TC is supplied with the data signal together with the data enable signal or a driving signal including the vertical synchronization signal, the horizontal synchronization signal, and the clock signal, from the image processor IP. The timing controller TC may output a gate timing control signal GDC for controlling an operation timing of the gate driver GD and a data timing control signal DDC for controlling an operation timing of the data driver DD and a data signal Data, based on the driving signal.

Further, the data driver DD samples and latches the data signal Data supplied from the timing controller TC in response to the data timing control signal DDC supplied from the timing controller TC to convert the data signal into a gamma reference voltage and output the converted gamma reference voltage. The data driver DD may output the data signal through a plurality of data lines DL.

Further, the gate driver GD may output the gate signal while shifting a level of the gate voltage, in response to the gate timing control signal GDC supplied from the timing controller TC. The gate driver GD may output the gate signal through a plurality of gate lines GL.

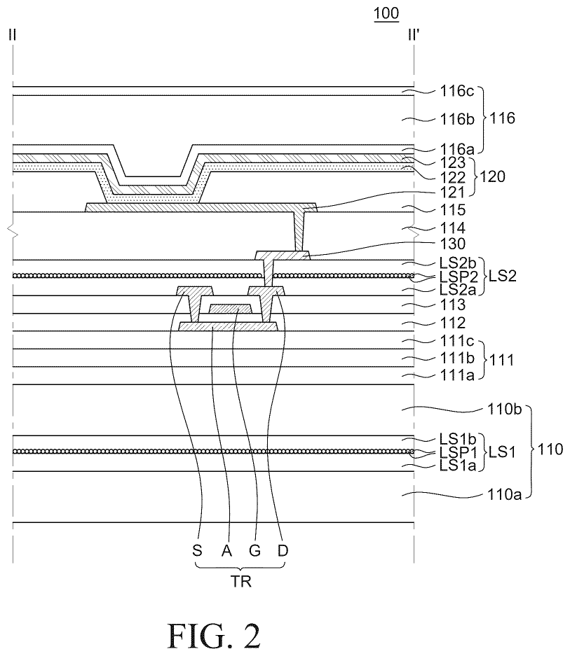

The display panel DP may display images while a pixel P emits light in response to the data signal and the gate signal supplied from the data driver DD and the gate driver GD. A detailed structure of the pixel P will be described in detail with reference to FIG. 2.

The display panel DP may include a display area DA and a non-display area NDA which encloses the display area DA.

The display area DA is an area where images are displayed in the display panel DP.

In the display area DA, a plurality of pixels P and a circuit for driving the plurality of pixels P may be disposed. The plurality of pixels P is a minimum unit which configures the display area DA and a display element may be disposed in each of the plurality of pixels P. For example, an organic light emitting diode which includes an anode, an emission layer, and a cathode may be disposed in each of the plurality of pixels P, but it is not limited thereto. Further, a circuit for driving the plurality of pixels P may include a driving element, a wiring line, and the like. For example, the circuit may be configured by a thin film transistor, a storage capacitor, a gate line, and a data line, but is not limited thereto.

The non-display area NDA is an area where no image is displayed.

The non-display area NDA is bent so as not to be seen from a front surface or blocked by a case and is also referred to as a bezel area.

Even though in FIG. 1, it is illustrated that the non-display area NDA encloses a quadrangular display area DA, shapes and placements of the display area DA and the non-display area NDA are not limited to the example illustrated in FIG. 1. That is, the display area DA and the non-display area NDA may have shapes suitable for a design of an electronic device including the display device 100. For example, an exemplary shape of the display area DA may be a pentagon, a hexagon, a circle, or an oval.

In the non-display area NDA, various wiring lines and circuits for driving the organic light emitting diode of the display area DA may be disposed. For example, in the non-display area NDA, a link line which transmits signals to the plurality of sub pixels and circuits of the display area DA, a gate-in-panel (GIP) line, or a driving IC, such as a gate driver GD or a data driver DD, may be disposed, but it is not limited thereto.

The display device 100 may further include various additional elements to generate various signals or drive the pixel in the display area DA. The additional elements for driving the pixels may include an inverter circuit, a multiplexer, or an electrostatic discharge (ESD) circuit. The display device 100 may further include an additional element associated with a function other than a function of driving a pixel. For example, the display device 100 may include additional elements which provide a touch sensing function, a user authentication function (for example, fingerprint recognition), a multilevel pressure sensing function, or a tactile feedback function. The above-mentioned additional elements may be located in the non-display area NDA and/or an external circuit which is connected to the connecting interface.

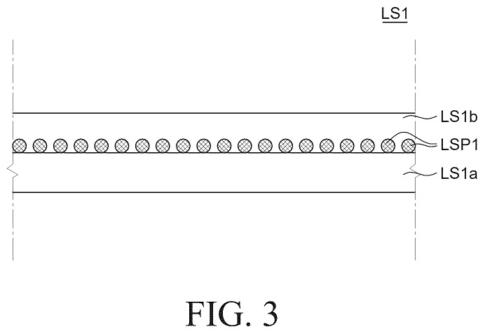

Here, a cross-sectional structure of the display area DA of the display device 100 will be described in more detail with reference to FIGS. 2 and 3 together.

FIG. 2 is a cross-sectional view taken along the line II-II′ of FIG. 1 according to one embodiment. FIG. 3 is an enlarged cross-sectional view of a first light shielding layer of a display device according to an exemplary embodiment of the present disclosure. FIG. 2 is a cross-sectional view illustrating a cross-sectional structure of one pixel disposed in the display area according to an exemplary embodiment of the present disclosure.

The display device 100 according to the exemplary embodiment of the present disclosure may include a substrate 110, a first light shielding layer LS1, a lower buffer layer 111, a transistor TR, a gate insulating layer 112, an interlayer insulating layer 113, a second light shielding layer LS2, a planarization layer 114, an auxiliary electrode 130, a bank 115, a light emitting diode 120, and an encapsulation unit 116.

The substrate 110 serves to support and protect components of the display device disposed there above.

The substrate 110 is a component for supporting various components included in the display device 100 and may be formed of an insulating material. The substrate 110 may include a first substrate 110a, a second substrate 110b, and a first light shielding layer LS1. The first light shielding layer LS1 may be disposed between the first substrate 110a and the second substrate 110b. As described above, the substrate 110 is configured by a triple layer of the first substrate 110a, the second substrate 110b, and the first light shielding layer LS1 to minimize or at least reduce the moisture permeation from the outside. However, the substrate 110 may be disposed as a single layer and the first light shielding layer LS1 may be disposed between the substrate 110 which is a single layer and a lower buffer layer 111, but the present disclosure is not limited thereto.

The first substrate 110a may have rigidity and flexibility. The first substrate 110a may be a configuration which substantially supports components of the display device 100, among configurations of the substrate 110. The first substrate 110a, for example, may be a flexible substrate which is formed of polyimide (PI), but is not limited thereto.

The first light shielding layer LS1 is disposed on the first substrate 110a. The first light shielding layer LS1 may be disposed on the entire surface of the first substrate 110a.

Referring to FIG. 3, the first light shielding layer LS1 includes a first insulating layer LS1a, a plurality of first particles LSP1, and a second insulating layer LS1b.

The first insulating layer LS1a is disposed on the entire surface of the first substrate 110a. The first insulating layer LS1a may be formed of an inorganic insulating material. For example, the first insulating layer LS1a may be formed by a single layer of silicon nitride (SiNx) or silicon oxide (SiOx) or a multi-layer thereof, but is not limited thereto.

The plurality of first particles LSP1 are disposed on the first insulating layer LS1a. The plurality of first particles LSP1 may be disposed between the first insulating layer LS1a and the second insulating layer LS1b. The plurality of first particles LSP1 may be disposed at an interface of the first insulating layer LS1a and the second insulating layer LS1b. Therefore, the plurality of first particles LSP1 are configured so as not to be in contact with an electrode or wiring lines disposed on the first light shielding layer LS1. For example, the plurality of first particles LSP1 are disposed on the first insulating layer LS1a after forming the first insulating layer LS1a and the second insulating layer LS1b is disposed on the plurality of first particles LSP1 so that the plurality of first particles may be disposed between the first insulating layer LS1a and the second insulating layer LS1b. However, it is not limited thereto.

The plurality of first particles LSP1 may be nano particles formed of a material including titanium (Ti). For example, the plurality of first particles LSP1 may be particles having a size of nano-meters (nm) formed by a sol-gel method, but is not limited thereto.

The plurality of first particles LSP1 may have a refractive index which is different from that of the first insulating layer LS1a and the second insulating layer LS1b. The plurality of first particles LSP1 may have a refractive index which is larger than that of the first insulating layer LS1a and the second insulating layer LS1b. For example, when the first insulating layer LS1a and the second insulating layer LS1b are formed of silicon dioxide (SiO₂) having a refractive index of approximately 1.46, the plurality of first particles LSP1 may be formed of titanium dioxide (TiO2) having a refractive index of approximately 2.61, but is not limited thereto.

In the meantime, in FIG. 3, it is illustrated that the plurality of first particles LSP1 are disposed to be spaced apart from each other with a constant interval. However, the plurality of first particles LSP1 may be disposed to be partially in contact with each other, or to be spaced apart from each other with various intervals, but is not limited thereto.

The second insulating layer LS1b may be disposed on the plurality of first particles LSP1 and the first insulating layer LS1a exposed from the plurality of first particles LSP1. The second insulating layer LS1b may be formed of an inorganic insulating material. For example, the second insulating layer LS1b may be formed by a single layer of silicon nitride (SiNx) or silicon oxide (SiOx) or a multi-layer thereof, but is not limited thereto.

The second substrate 110b is disposed on the first light shielding layer LS1. The second substrate 110b is disposed on the second insulating layer LS1b of the first light shielding layer LS1. The second substrate 110b may have rigidity and flexibility. The second substrate 110b may be a configuration which substantially supports components of the display device 100, among configurations of the substrate 110, together with the first substrate 110a. The second substrate 110b, for example, may be a flexible substrate which is formed of polyimide (PI), but is not limited thereto.

The lower buffer layer 111 is disposed on the substrate 110. The lower buffer layer 111 is disposed below the transistor TR to delay diffusion of moisture and oxygen which has permeated into the substrate 110, to the transistor TR.

The lower buffer layer 111 may include a first lower buffer layer 111a, a second lower buffer layer 111b, and a third lower buffer layer 111c. The lower buffer layer 111 is formed of a plurality of layers which includes a first lower buffer layer 111a, a second lower buffer layer 111b, and a third lower buffer layer 111c. Therefore, even though the lower buffer layer 111 may be referred to as a multi-buffer layer, the lower buffer layer 111 may be formed by a single layer or may be formed of a plurality of layers, other than three layers, but is not limited thereto.

For example, the first lower buffer layer 111a may be formed by a single layer of any one of amorphous silicon (a-Si), silicon nitride (SiNx), and silicon oxide (SiOx) or a plurality of layers thereof, but is not limited thereto.

For example, the second lower buffer layer 111b may be formed by a single layer of any one of amorphous silicon (a-Si), silicon nitride (SiNx), and silicon oxide (SiOx) or a plurality of layers thereof, but is not limited thereto.

For example, the third lower buffer layer 111c may be formed by a single layer of any one of amorphous silicon (a-Si), silicon nitride (SiNx), and silicon oxide (SiOx) or a plurality of layers thereof, but is not limited thereto.

The transistor TR is disposed on the lower buffer layer 111. The transistor TR may include an active layer A, a gate electrode G, a source electrode S, and a drain electrode D. Here, depending on the design of the pixel circuit, the source electrode S may serve as a drain electrode and the drain electrode D may serve as a source electrode.

The active layer A is disposed on the lower buffer layer 111. The active layer A may include low temperature polycrystalline silicon (LTPS) such as amorphous silicon or polycrystalline silicon or include an oxide semiconductor material formed of metal oxide, such as indium-gallium-zinc-oxide (IGZO), indium-zinc-oxide (IZO), indium-gallium-tin-oxide (IGTO), or indium-gallium-oxide (IGO).

For example, the active layer A may include a channel region in which a channel is formed when the transistor TR is driven and a source region and a drain region on both sides of the channel region. The source region refers to a portion of the active layer A which is connected to the source electrode S and the drain region refers to a portion of the active layer A which is connected to the drain electrode D. For example, the source region and the drain region may be configured by ion-doping (impurity doping) of the active layer A. The source region and the drain region may be generated by doping ions into the polycrystalline silicon material and the channel region may refer to a part in which the ions are not doped, but the polycrystalline silicon material remains.

A gate insulating layer 112 may be disposed on the active layer A. The gate insulating layer 112 may be formed as a single layer of silicon nitride (SiNx) or silicon oxide (SiOx) or a multi-layer thereof. In the gate insulating layer 112, contact holes through which the source electrode S and the drain electrode D of the transistor TR are connected to the source region and the drain region of the active layer A of the transistor TR may be formed.

The gate electrode G of the transistor TR may be disposed on the gate insulating layer 112.

For example, the gate electrode G may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The gate electrode G may be formed on the gate insulating layer 112 so as to overlap the channel region of the active layer A of the transistor TR.

The interlayer insulating layer 113 may be disposed on the gate insulating layer 112 and the gate electrode G. The interlayer insulating layer 113 may be configured by a single layer of silicon nitride (SiNx) or silicon oxide (SiOx) or a multi-layer thereof.

The source electrode S and the drain electrode D are disposed on the interlayer insulating layer 113. The source electrode S and the drain electrode D may be electrically connected to the active layer A of the transistor TR through the contact hole of the interlayer insulating layer 113.

The source electrode S and the drain electrode D may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The second light shielding layer LS2 is disposed on the source electrode S and the drain electrode D. The second light shielding layer LS2 may be disposed so as to correspond to the entire surface above the substrate 110. The second light shielding layer LS2 includes an inorganic insulating material and may be configured to protect an upper portion of the transistor TR. Further, the second light shielding layer LS2 may insulate between the transistor TR and the auxiliary electrode 130. Therefore, the second light shielding layer LS2 may be referred to as a passivation layer, but is not limited thereto.

The second light shielding layer LS2 includes the first insulating layer LS2a, the plurality of second particles LSP2, and the second insulating layer LS2b.

The first insulating layer LS2a may be formed of an inorganic insulating material. For example, the first insulating layer LS2a may be formed by a single layer of silicon nitride (SiNx) or silicon oxide (SiOx) or a multi-layer thereof, but is not limited thereto.

The plurality of second particles LSP2 may be disposed between the first insulating layer LS2a and the second insulating layer LS2b. The plurality of second particles LSP2 may be disposed at the interface of the first insulating layer LS2a and the second insulating layer LS2b. For example, the plurality of second particles LSP2 is disposed on the first insulating layer LS2a after forming the first insulating layer LS2a and the second insulating layer LS2b is disposed on the plurality of second particles LSP2 so that the plurality of second particles may be disposed between the first insulating layer LS2a and the second insulating layer LS2b. However, it is not limited thereto.

The plurality of second particles LSP2 may be nano particles formed of a material including titanium (Ti). For example, the plurality of second particles LSP2 may be particles having a size of nano-meters (nm) formed by a sol-gel method, but is not limited thereto.

The plurality of second particles LSP2 may have a refractive index which is different from that of the first insulating layer LS2a and the second insulating layer LS2b. The plurality of second particles LSP2 may have a refractive index which is larger than that of the first insulating layer LS2a and the second insulating layer LS2b. For example, when the first insulating layer LS2a and the second insulating layer LS2b are formed of silicon dioxide (SiO2) having a refractive index of approximately 1.46, the plurality of second particles LSP2 is formed of titanium dioxide (TiO2) having a refractive index of approximately 2.61, but is not limited thereto.

The second insulating layer LS2b may be formed of an inorganic insulating material. For example, the second insulating layer LS2b may be formed by a single layer of silicon nitride (SiNx) or silicon oxide (SiOx) or a multi-layer thereof, but is not limited thereto.

The auxiliary electrode 130 is disposed on the second light shielding layer LS2. The auxiliary electrode 130 may be connected to the drain electrode D of the transistor TR through the contact holes of the second light shielding layer LS2. Therefore, the auxiliary electrode 130 may be configured to electrically connect the transistor TR and the light emitting diode 120.

The auxiliary electrode 130 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The planarization layer 114 is disposed on the second light shielding layer LS2 and the auxiliary electrode 130. The planarization layer 114 may be an organic layer which planarizes and protects an upper portion of the transistor TR. For example, the planarization layer 114 may be formed of an organic material such as acryl resin, epoxy resin, phenolic resin, polyamide resin, or polyimide resin, but is not limited thereto.

The light emitting diode 120 is disposed on the planarization layer 114 and the auxiliary electrode 130.

The light emitting diode 120 includes an anode 121, an emission layer 122, and a cathode 123.

The anode 121 is disposed on the planarization layer 114. The anode 121 may be connected to the auxiliary electrode 130 by means of a contact hole of the planarization layer 114 and may be electrically connected to the transistor TR. The anode 121 may be formed of a metallic material.

When the display device 100 is a top emission type in which light emitted from the light emitting diode 120 is emitted above the substrate 110 on which the light emitting diode 120 is disposed, the anode 121 may further include a reflective layer and a transparent conductive layer disposed on the reflective layer. The transparent conductive layer may be formed of transparent conductive oxide such as indium tin oxide (ITO) or indium zinc oxide (IZO). The reflective layer may be formed of silver (Ag), aluminum (Al), gold (Au), molybdenum (Mo), tungsten (W), chrome (Cr), or an alloy thereof, but they are not limited thereto.

The bank 115 is disposed on the anode 121. The bank 115 may be disposed while covering an end of the anode 121. A part of the bank 115 corresponding to an emission area of the sub pixel may be open. A part of the anode 121 may be exposed through the open part of the bank 115 (hereinafter, referred to as an open area). At this time, the bank 115 may be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

The emission layer 122 is disposed on the anode 121 and the bank 115. The emission layer 122 may be disposed in the open area of the bank 115 and in the vicinity of the open area of the bank. Therefore, the emission layer 122 may be disposed on the anode 121 exposed through the open area of the bank 115.

The emission layer 122 may include a plurality of organic material layers. For example, the emission layer 122 may include an organic material layer such as a hole injection layer, a hole transport layer, an electron transport layer, and an electron injection layer. In the meantime, when the emission layer 122 emits white light, light emitted from the emission layer 122 may be converted into light with various colors by a plurality of color filters, but is not limited thereto.

The cathode 123 is disposed on the emission layer 122. The cathode 123 supplies electrons to the emission layer 122 so that the cathode may be formed of a conductive material having a low work function. The cathode 123 may be formed as one layer over the plurality of sub pixels. That is, the cathodes 123 of the plurality of sub pixels SP are connected to be integrally formed.

For example, the cathode 123 may be formed of a transparent conductive material such as indium tin oxide (ITO) and indium zinc oxide (IZO) or ytterbium (Yb) alloy and may further include a metal doping layer, but is not limited thereto.

The encapsulation layer 116 is disposed on the light emitting diode 120.

The encapsulation layer 116 may have a multi-layered structure including a first encapsulation layer 116a, a second encapsulation layer 116b, and a third encapsulation layer 116c. However, the encapsulation layer may be formed with a single layer structure, but is not limited thereto.

The first encapsulation layer 116a and the third encapsulation layer 116c are formed of inorganic materials and the second encapsulation layer 116b may be formed of an organic material. The second encapsulation layer 116b may be the thickest among the first encapsulation layer 116a, the second encapsulation layer 116b, and the third encapsulation layer 116c. The second encapsulation layer 116b may planarize an upper portion of the light emitting diode 120.

The first encapsulation layer 116a is disposed on the cathode 123 and may be disposed to be most adjacent to the light emitting diode 120. The first encapsulation layer 116a may be formed of an inorganic insulating material on which low-temperature deposition may be performed. For example, the first encapsulation layer 116a is configured by silicon nitride (SiNx), silicon oxide (SiOx), silicon oxynitride (SiON), or aluminum oxide (Al2O3), but is not limited thereto.

In the meantime, the first encapsulation layer 116a is deposited under a low temperature atmosphere so that during the deposition process, the damage of the light emitting layer 122 including an organic material which is vulnerable to the high temperature atmosphere may be suppressed.

The second encapsulation layer 116b is disposed on the first encapsulation layer 116a. The second encapsulation layer 116b may be disposed to have a smaller area than that of the first encapsulation layer 116a. In this case, the second encapsulation layer 116b may be formed to expose both ends of the first encapsulation layer 116a. The second encapsulation layer 116b may serve as a buffer to alleviate stress between the layers due to bending of the display device 100 and to enhance planarization performance.

For example, the second encapsulation layer 116b may be formed of an organic insulating material, such as acrylic resin, epoxy resin, polyimide, polyethylene, or silicon oxy carbon (SiOC). For example, the second encapsulation layer 116b may be formed by an inkjet method, but is not limited thereto.

The third encapsulation layer 116c may be formed above the substrate 110 on which the second encapsulation layer 116b may be formed so as to cover upper surfaces and side surfaces of the second encapsulation layer 116b and the first encapsulation layer 116a. At this time, the third encapsulation layer 116c may minimize or block the permeation of external moisture or oxygen into the first encapsulation layer 116a and the second encapsulation layer 116b. For example, the third encapsulation layer 116c may be configured by an inorganic insulating material, such as silicon nitride (SiNx), silicon oxide (SiOx), silicon oxynitride (SiON), or aluminum oxide (Al2O3), but may be limited thereto.

In the meantime, even though it is not illustrated, a touch sensing layer, a polarization layer, and a cover glass may be disposed on the encapsulation layer 116.

The touch sensing layer may include a touch buffer layer, a touch interlayer insulating layer, and a touch electrode. The touch electrode may include a touch sensor metal and a bridge metal which are located on different layers.

For example, the touch buffer layer is disposed on the third encapsulation layer 116c and the touch sensor metal may be disposed on the touch buffer layer. The touch interlayer insulating layer is disposed on the touch sensor metal and the bridge metal may be disposed on the touch interlayer insulating layer.

The touch buffer layer and the touch interlayer insulating layer may be formed of an inorganic insulating material or an organic insulating material. Therefore, the touch buffer layer and the touch interlayer insulating layer may minimize a step at a point where the touch electrode is disposed and electrically insulate the touch sensor metal and the bridge metal from each other.

The polarization layer may be disposed on the touch sensing layer.

The polarization layer suppresses reflection of external light on the display area DA of the substrate 110. When the display device 100 is used at the outside, external natural light enters to be reflected by a reflective layer included in the anode 121 of the light emitting diode 120 or reflected by an electrode which is formed of a metal and disposed below the light emitting diode 120. Therefore, the image of the display device 100 may not be visibly recognized due to the light reflected as described above. The polarization layer polarizes the light entering from the outside to a specific direction and suppresses the reflected light from being emitted to the outside of the display device 100.

The cover glass may be disposed on the polarization layer. The cover glass protects the component of the display device 100 from the external shocks and may suppress damages such as a scratch. The cover glass may be adhered to the polarization layer by the adhesive layer. The adhesive layer serves to adhere the components of the display device 100 to each other, and for example, may be formed using an optically clear display adhesive, such as a pressure sensitive adhesive, an optical clear adhesive (OCA) or an optical clear resin (OCR), but is not limited thereto.

In the display device, a protective layer formed of metal which shields external light is disposed below the active layer of the transistor. The protective layer suppresses fluctuation of an element characteristic of a transistor due to the damaged active layer due to the external light, for example, fluctuation of a threshold voltage or an on/off voltage to suppress the imbalanced luminance between pixels. Specifically, the light shielding described above may be further requested for the active layer which is formed of an oxide semiconductor which is further vulnerable to the damage due to the external light. However, it may be difficult to protect the active layer from internal light emitted from the light emitting diode disposed above the transistor, only with the protective layer disposed below the active layer. Further, in the display device, various electrodes and wiring lines which are formed of metal are disposed so that there is an additional problem in that it is difficult to shield all external light and internal light which are guided to the active layer from various paths by the electrodes and wiring lines.

In the display device 100 according to the exemplary embodiment of the present disclosure, the first light shielding layer LS1 is disposed below the transistor TR and the second light shielding layer LS2 is disposed above the transistor TR to shield light of various paths guided to the transistor TR.

Specifically, in the display device 100 according to the exemplary embodiment of the present disclosure, the first light shielding layer LS1 is disposed between the first substrate 110a and the transistor TR and the second light shielding layer LS2 is disposed between the transistor TR and the light emitting diode 120. The first light shielding layer LS1 and the second light shielding layer LS2 may be disposed so as to correspond to the entire surface on the first substrate 110a. Each of the first light shielding layer LS1 and the second light shielding layer LS2 is configured to have a structure in which a plurality of particles LSP1 and LSP2 is disposed between first insulating layers LS1a and LS2a and second insulating layers LS1b and LS2b. At this time, the plurality of particles LSP1 and LSP2 are formed of a material having a refractive index higher than that of the first insulating layers LS1a and LS2a and the second insulating layers LS1b and LS2b to scatter or reflect light which is guided to the plurality of particles LSP1 and LSP2. Therefore, the first light shielding layer LS1 and the second light shielding layer LS2 may be configured to shield external light and internal light guided to the active layer A through various paths. Accordingly, in the display device 100 according to the exemplary embodiment of the present disclosure, the first light shielding layer LS1 is disposed below the transistor TR and the second light shielding layer LS2 is disposed above the transistor TR to shield light of various paths guided to the transistor TR and to improve the reliability of the transistor TR.

In the meantime, in the display device 100 according to the exemplary embodiment of the present disclosure, the first light shielding layer LS1 and the second light shielding layer LS2 include inorganic insulating materials to serve as a light shielding layer for protecting the active layer A and also serve as an insulating layer for insulating components of the display device 100. Therefore, in the display device 100 according to the exemplary embodiment of the present disclosure, the first light shielding layer LS1 and the second light shielding layer LS2 serve as both the light shielding layer and the insulating layer so that the configuration of the display device 100 may be simplified.

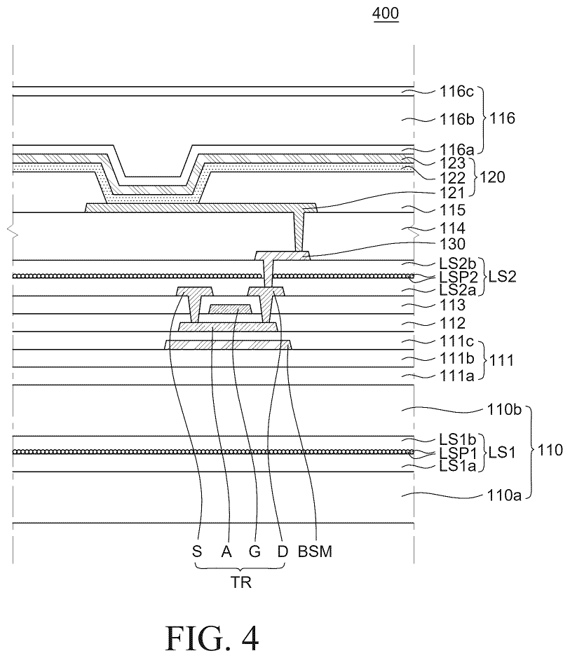

FIG. 4 is a cross-sectional view of a display device according to another exemplary embodiment of the present disclosure. The only difference between a display device 400 of FIG. 4 and the display device 100 of FIGS. 1 to 3 is that a protective layer BSM is further disposed, but the other configuration is the same, so that a redundant description will be omitted.

Referring to FIG. 4, a protective layer BSM is disposed below the active layer A. The protective layer BSM is disposed between the first light shielding layer LS1 and the active layer A of the transistor TR. The protective layer BSM may be insulated from the active layer A. For example, the protective layer BSM is disposed on the second lower buffer layer 111b and the third lower buffer layer 111c is disposed on the protective layer BSM to insulate the protective layer BSM from the active layer A, but is not limited thereto.

The protective layer BSM may be formed of a metal material having a low light transmittance and may reflect light which is incident onto the active layer A from the bottom of the active layer A. The protective layer BSM shields light which is incident onto the active layer A and may protect the active layer A. For example, the protective layer BSM may be referred to as a bottom shield metal (BSM), but is not limited thereto. For example, the protective layer BSM may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

In the display device 400 according to another exemplary embodiment of the present disclosure, the protective layer BSM is disposed between the first light shielding layer LS1 and the active layer A of the transistor TR. Therefore, the protective layer BSM may be configured to further shield external light and internal light of various paths guided to the active layer A, together with the first light shielding layer LS1 and the second light shielding layer LS2. Accordingly, in the display device 400 according to another exemplary embodiment of the present disclosure, the damage of the active layer A may be further minimized and the reliability of the transistor TR may be further improved.

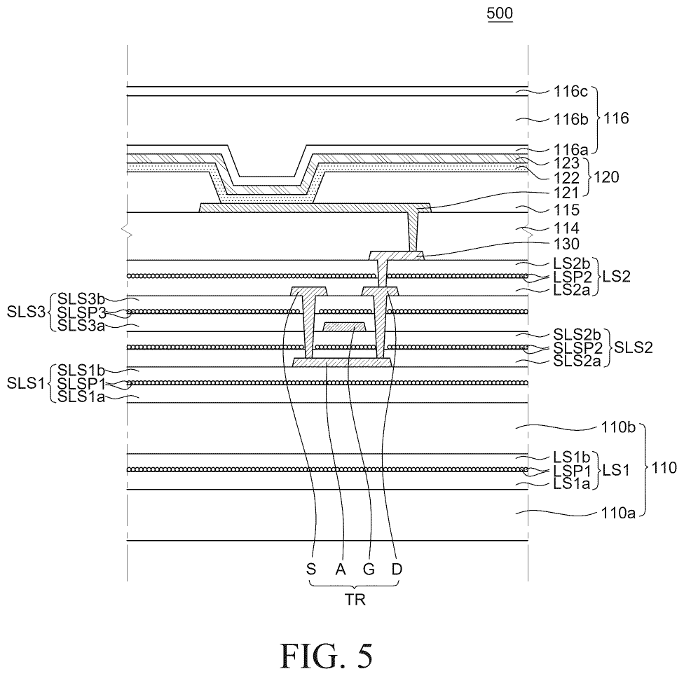

FIG. 5 is a cross-sectional view of a display device according to still another exemplary embodiment of the present disclosure. The only difference between a display device 500 of FIG. 5 and the display device 100 of FIGS. 1 to 3 is that a first sub light shielding layer SLS1, a second sub light shielding layer SLS2, and a third sub light shielding layer SLS3 are further disposed, but the other configuration is the same, so that a redundant description will be omitted.

Referring to FIG. 5, the display device 500 according to still another exemplary embodiment of the present disclosure further includes a first sub light shielding layer SLS1, a second sub light shielding layer SLS2, and a third sub light shielding layer SLS3 disposed between the first light shielding layer LS1 and the second light shielding layer LS2.

The first sub light shielding layer SLS1 is disposed on the substrate 110. The first sub light shielding layer SLS1 is disposed between the substrate 110 and the transistor TR. The first sub light shielding layer SLS1 may be disposed between the second substrate 110b and the active layer A. The first sub light shielding layer SLS1 may be disposed so as to insulate a conductive component. For example, the first sub light shielding layer SLS1 may be disposed to insulate the substrate 110 and the transistor TR. Therefore, the first sub light shielding layer SLS1 may be referred to as a buffer layer, but is not limited thereto.

The first sub light shielding layer SLS1 includes a first insulating layer SLS1a, a plurality of first sub particles SLSP1, and a second insulating layer SLS1b.

The first insulating layer SLS1a may be disposed so as to correspond to the entire surface on the second substrate 110b. The first insulating layer SLS1a may be formed of an inorganic insulating material. For example, the first insulating layer SLS1a may be formed by a single layer of silicon nitride (SiNx) or silicon oxide (SiOx) or a multi-layer thereof, but is not limited thereto.

The plurality of first sub particles SLSP1 are disposed on the first insulating layer SLS1a. The plurality of first sub particles SLSP1 may be disposed between the first insulating layer SLS1a and the second insulating layer SLS1b. The plurality of first sub particles SLSP1 may be disposed at an interface of the first insulating layer SLS1a and the second insulating layer SLS1b. For example, the plurality of first sub particles SLSP1 are disposed on the first insulating layer SLS1a after forming the first insulating layer SLS1a and the second insulating layer SLS1b are disposed on the plurality of first sub particles SLSP1 so that the plurality of first sub particles are disposed between the first insulating layer SLS1a and the second insulating layer SLS1b. However, it is not limited thereto.

The plurality of first sub particles SLSP1 may be nano particles formed of a material including titanium (Ti). For example, the plurality of first sub particles SLSP1 may be particles having a size of nano-meters (nm) formed by a sol-gel method, but is not limited thereto.

The plurality of first sub particles SLSP1 may have a refractive index which is different from that of the first insulating layer SLS1a and the second insulating layer SLS1b. The plurality of first sub particles SLSP1 may have a refractive index larger than that of the first insulating layer SLS1a and the second insulating layer SLS1b. For example, when the first insulating layer SLS1a and the second insulating layer SLS1b are formed of silicon dioxide (SiO2) having a refractive index of approximately 1.46, the plurality of first sub particles SLSP1 is formed of titanium dioxide (TiO2) having a refractive index of approximately 2.61, but is not limited thereto.

The second insulating layer SLS1b may be disposed on the plurality of first sub particles SLSP1 and the first insulating layer SLS1a exposed from the plurality of first sub particles SLSP1. The second insulating layer SLS1b may be formed of an inorganic insulating material. For example, the second insulating layer SLS1b may be formed by a single layer of silicon nitride (SiNx) or silicon oxide (SiOx) or a multi-layer thereof, but is not limited thereto.

The second sub light shielding layer SLS2 is disposed on the first sub light shielding layer SLS1 and the active layer A. The second sub light shielding layer SLS2 is disposed between the active layer A and the first sub light shielding layer SLS1 and the gate electrode G and the third sub light shielding layer SLS3. The second sub light shielding layer SLS2 may be disposed between the active layer A and the gate electrode G. The second sub light shielding layer SLS2 may be disposed so as to insulate a conductive component. For example, the second sub light shielding layer SLS2 may be disposed to insulate the active layer A and the gate electrode G from each other. Therefore, the second sub light shielding layer SLS2 may be referred to as a gate insulating layer, but is not limited thereto.

The second sub light shielding layer SLS2 includes a first insulating layer SLS2a, a plurality of second sub particles SLSP2, and a second insulating layer SLS2b.

The first insulating layer SLS2a is disposed on the first sub light shielding layer SLS1 and the active layer A. The first insulating layer SLS2a may be formed of an inorganic insulating material. For example, the first insulating layer SLS2a may be formed by a single layer of silicon nitride (SiNx) or silicon oxide (SiOx) or a multi-layer thereof, but is not limited thereto.

The plurality of second sub particles SLSP2 are disposed on the first insulating layer SLS2a. The plurality of second sub particles SLSP2 may be disposed between the first insulating layer SLS2a and the second insulating layer SLS2b. The plurality of second sub particles SLSP2 may be disposed at the interface of the first insulating layer SLS2a and the second insulating layer SLS2b. For example, the plurality of second sub particles SLSP2 are disposed on the first insulating layer SLS2a after forming the first insulating layer SLS2a and the second insulating layer SLS2b is disposed on the plurality of second sub particles SLSP2 so that the plurality of second sub particles are disposed between the first insulating layer SLS2a and the second insulating layer SLS2b. However, it is not limited thereto.

The plurality of second sub particles SLSP2 may be nano particles formed of a material including titanium (Ti). For example, the plurality of second sub particles SLSP2 may be particles having a size of nano-meters (nm) formed by a sol-gel method, but is not limited thereto.

The plurality of second sub particles SLSP2 may have a refractive index which is different from that of the first insulating layer SLS2a and the second insulating layer SLS2b. The plurality of second sub particles SLSP2 may have a refractive index larger than that of the first insulating layer SLS2a and the second insulating layer SLS2b. For example, when the first insulating layer SLS2a and the second insulating layer SLS2b are formed of silicon dioxide (SiO₂) having a refractive index of approximately 1.46, the plurality of second sub particles SLSP2 is formed of titanium dioxide (TiO2) having a refractive index of approximately 2.61, but is not limited thereto.

The second insulating layer SLS2b may be disposed on the plurality of second sub particles SLSP2 and the first insulating layer SLS2a exposed from the plurality of second sub particles SLSP2. The second insulating layer SLS2b may be formed of an inorganic insulating material. For example, the second insulating layer SLS2b may be formed by a single layer of silicon nitride (SiNx) or silicon oxide (SiOx) or a multi-layer thereof, but is not limited thereto.

The third sub light shielding layer SLS3 is disposed on the second sub light shielding layer SLS2 and the gate electrode G. The third sub light shielding layer SLS3 is disposed between the second sub light shielding layer SLS2 and the gate electrode G and the source electrode S, the drain electrode D, and the second light shielding layer LS2. The third sub light shielding layer SLS3 may be disposed between the gate electrode G and the source electrode S and the drain electrode D. The third sub light shielding layer SLS3 may be disposed so as to insulate a conductive component. For example, the third sub light shielding layer SLS3 may be disposed to insulate the gate electrode G from the source electrode S and the drain electrode D. Therefore, the third sub light shielding layer SLS3 may be referred to as a lower interlayer insulating layer, but is not limited thereto.

The third sub light shielding layer SLS3 includes a first insulating layer SLS3a, a plurality of third sub particles SLSP3, and a second insulating layer SLS3b.

The first insulating layer SLS3a is disposed on the second sub light shielding layer SLS2 and the gate electrode G. The first insulating layer SLS3a may be formed of an inorganic insulating material. For example, the first insulating layer SLS3a may be formed by a single layer of silicon nitride (SiNx) or silicon oxide (SiOx) or a multi-layer thereof, but is not limited thereto.

The plurality of third sub particles SLSP3 are disposed on the first insulating layer SLS3a. The plurality of third sub particles SLSP3 may be disposed between the first insulating layer SLS3a and the second insulating layer SLS3b. The plurality of third sub particles SLSP3 may be disposed at an interface of the first insulating layer SLS3a and the second insulating layer SLS3b. For example, the plurality of third sub particles SLSP3 are disposed on the first insulating layer SLS3a after forming the first insulating layer SLS3a and the second insulating layer SLS3b is disposed on the plurality of third sub particles SLSP3 so that the plurality of third sub particles may be disposed between the first insulating layer SLS3a and the second insulating layer SLS3b. However, it is not limited thereto.

The plurality of third sub particles SLSP3 may be nano particles formed of a material including titanium (Ti). For example, the plurality of third sub particles SLSP3 may be particles having a size of nano-meters (nm) formed by a sol-gel method, but is not limited thereto.

The plurality of third sub particles SLSP3 may have a refractive index which is different from that of the first insulating layer SLS3a and the second insulating layer SLS3b. The plurality of third sub particles SLSP3 may have a refractive index larger than that of the first insulating layer SLS3a and the second insulating layer SLS3b. For example, when the first insulating layer SLS3a and the second insulating layer SLS3b are formed of silicon dioxide (SiO2) having a refractive index of approximately 1.46, the plurality of third sub particles SLSP3 may be formed of titanium dioxide (TiO2) having a refractive index of approximately 2.61, but is not limited thereto.

The second insulating layer SLS3b may be disposed on the plurality of third sub particles SLSP3 and the first insulating layer SLS3a exposed from the plurality of third sub particles SLSP3. The second insulating layer SLS3b may be formed of an inorganic insulating material. For example, the second insulating layer SLS3b may be formed by a single layer of silicon nitride (SiNx) or silicon oxide (SiOx) or a multi-layer thereof, but is not limited thereto.

In the meantime, in FIG. 5, it is illustrated that each of the first sub light shielding layer SLS1, the second sub light shielding layer SLS2, and the third sub light shielding layer SLS3 includes the first insulating layer, the plurality of particles, and the second insulating layer. However, at least a part of the first sub light shielding layer SLS1, the second sub light shielding layer SLS2, and the third sub light shielding layer SLS3 may include the first insulating layer, the plurality of particles, and the second insulating layer. Further, a part of the first sub light shielding layer SLS1, the second sub light shielding layer SLS2, and the third sub light shielding layer SLS3 may not include the plurality of particles. However, the present disclosure is not limited thereto.

In the display device 500 according to still another exemplary embodiment of the present disclosure, a first sub light shielding layer SLS1, a second sub light shielding layer SLS2, and a third sub light shielding layer SLS3 are further disposed between the first light shielding layer LS1 and the second light shielding layer LS2. Therefore, the first sub light shielding layer SLS1, the second sub light shielding layer SLS2, and the third sub light shielding layer SLS3 may be configured to further shield external light and internal light of various paths guided to the active layer A, together with the first light shielding layer LS1 and the second light shielding layer LS2. Accordingly, in the display device 500 according to still another exemplary embodiment of the present disclosure, the damage of the active layer A may be further minimized and the reliability of the transistor TR may be further improved.

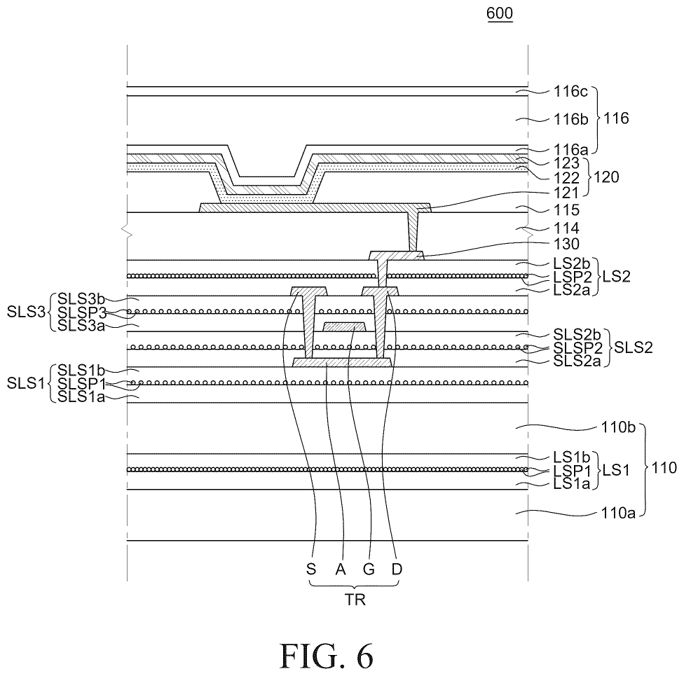

FIG. 6 is a cross-sectional view of a display device according to still another exemplary embodiment of the present disclosure. The only difference between a display device 600 of FIG. 6 and the display device 500 of FIG. 5 is that the density of a plurality of sub particles SLSP1, SLSP2, and SLSP3 of a first sub light shielding layer SLS1, a second sub light shielding layer SLS2, and a third sub light shielding layer SLS3 is different, but the other configuration is the same, so that a redundant description will be omitted.

Referring to FIG. 6, the density of the plurality of sub particles SLSP1, SLSP2, and SLSP3 of the first sub light shielding layer SLS1, the second sub light shielding layer SLS2, and the third sub light shielding layer SLS3 is lower than the density of the plurality of particles LSP1 and LSP2 of the first light shielding layer LS1 and the second light shielding layer LS2. The density of the plurality of sub particles SLSP1, SLSP2, and SLSP3 included in the first sub light shielding layer SLS1, the second sub light shielding layer SLS2, and the third sub light shielding layer SLS3 is lower than the density of the plurality of particles LSP1 and LSP2 included in the first light shielding layer LS1 and the second light shielding layer LS2. The density of the plurality of first sub particles SLSP1, the plurality of second sub particles SLSP2, and the plurality of third sub particles SLSP3 included in the first sub light shielding layer SLS1, the second sub light shielding layer SLS2, and the third sub light shielding layer SLS3 may be lower than the density of the plurality of first particles LSP1 and the plurality of second particles LSP2 included in the first light shielding layer LS1 and the second light shielding layer LS2. An amount of the plurality of sub particles SLSP1, SLSP2, and SLSP3 formed by the sol-gel method is adjusted by changing an amount of precursors used when the plurality of sub particles SLSP1, SLSP2, and SLSP3 is formed using the sol-gel method as an example to control the density of the plurality of sub particles SLSP1, SLSP2, and SLSP3. However, the present disclosure is not limited thereto.

In the display device 600 according to still another exemplary embodiment of the present disclosure, the density of the plurality of sub particles SLSP1, SLSP2, and SLSP3 of the first sub light shielding layer SLS1, the second sub light shielding layer SLS2, and the third sub light shielding layer SLS3 is configured to be lower than the density of the plurality of particles LSP1 and LSP2 of the first light shielding layer LS1 and the second light shielding layer LS2. By doing this, out gassing of the peripheral portion of the transistor may be minimized or at least reduced.

Specifically, the plurality of particles LSP1 and LSP2 and the plurality of sub particles SLSP1, SLSP2, and SLSP3 may be formed by the sol-gel method as an example. However, in the plurality of particles LSP1 and LSP2 and the plurality of sub particles SLSP1, SLSP2, and SLSP3 formed by the sol-gel method, for example, out gassing may be generated by a solvent which is not completely evaporated. At this time, various components, such as an active layer, which is specifically vulnerable to moisture permeation, are disposed on the transistor. Therefore, when out gassing is generated from the insulating layer disposed in the peripheral portion of the transistor, there is a problem in that moisture permeates into components of the transistor through a crack of the insulating layer generated by the out gassing. Accordingly, in the display device 600 according to still another exemplary embodiment of the present disclosure, the density of the plurality of sub particles SLSP1, SLSP2, and SLSP3 of the first sub light shielding layer SLS1, the second sub light shielding layer SLS2, and the third sub light shielding layer SLS3 disposed in the peripheral portion of the transistor is configured to be lower than the density of the plurality of particles LSP1 and LSP2 of the first light shielding layer LS1 and the second light shielding layer LS2. By doing this, out gassing of the peripheral portion of the transistor TR may be minimized or at least reduced and the reliability of the transistor TR may be further improved.

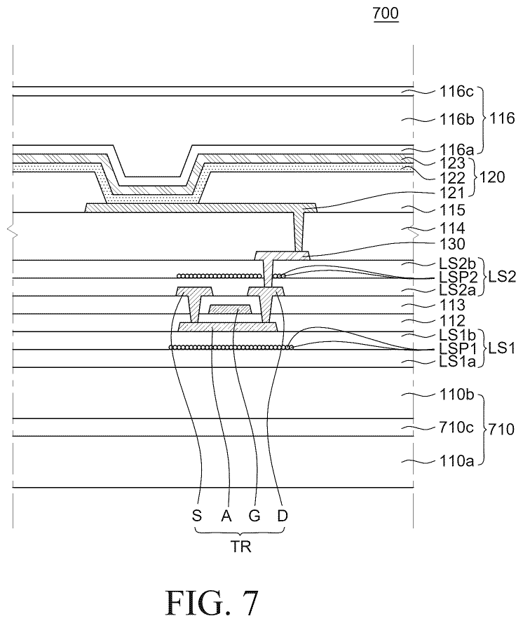

FIG. 7 is a cross-sectional view of a display device according to still another exemplary embodiment of the present disclosure. The only difference between the display device 700 of FIG. 7 and the display device 100 of FIGS. 1 to 3 is that the first light shielding layer LS1 and the second light shielding layer LS2 are disposed only in an area overlapping the active layer A, but the other configuration is substantially the same, so that a redundant description will be omitted.

Referring to FIG. 7, the substrate 710 includes a first substrate 110a, an inorganic insulating layer 710c, and the second substrate 110b. The inorganic insulating film 710c may be disposed between the first substrate 110a and the second substrate 110b. As described above, the substrate 710 is configured by a triple layer of the first substrate 110a, the inorganic insulating layer 710c, and the second substrate 110b to minimize the moisture permeation from the outside.

The inorganic insulating layer 710c is disposed on the entire surface of the first substrate 110a. The inorganic insulating layer 710c may be formed of an inorganic insulating material. For example, the inorganic insulating layer 710c may be formed by a single layer of silicon nitride (SiNx) or silicon oxide (SiOx) or a multi-layer thereof, but is not limited thereto.

Referring to FIG. 7, the first light shielding layer LS1 is disposed on the substrate 710. The plurality of first particles LSP1 of the first light shielding layer LS1 are disposed only in an area overlapping the active layer A. The plurality of first particles LSP1 are patterned by processes of patterning a photoresist using a mask, coating and drying a material for forming the plurality of first particles LSP1, and then removing a photoresist to be disposed only in the area overlapping the active layer A, but is not limited thereto.

In the meantime, the plurality of first particles LSP1 may also be disposed so as to overlap components which are formed simultaneously with the active layer A on the same layer as the active layer A. At this time, the plurality of first particles LSP1 are also disposed with the same pattern as the active layer A so that the plurality of first particles may be disposed using the same mask as the active layer A. Therefore, in the display device 700 according to still another exemplary embodiment of the present disclosure, a separate mask may not be added when the plurality of first particles LSP1 are patterned so that the number of masks may be minimized or at least reduced, but is not limited thereto.

Referring to FIG. 7, the second light shielding layer LS2 is disposed on the interlayer insulating layer 113, the source electrode S, and the drain electrode D. The plurality of second particles LSP2 of the second light shielding layer LS2 are disposed only in an area overlapping the active layer A. The plurality of second particles LSP2 are patterned by processes of patterning a photoresist using a mask, coating and drying a material for forming the plurality of second particles LSP2, and then removing a photoresist to be disposed only in the area overlapping the active layer A, but is not limited thereto.

In the meantime, the plurality of second particles LSP2 may also be disposed so as to overlap components which are formed simultaneously with the active layer A on the same layer as the active layer A. At this time, the plurality of second particles LSP2 are also disposed with the same pattern as the active layer A so that the plurality of second particles may be disposed using the same mask as the active layer A. Therefore, in the display device 700 according to still another exemplary embodiment of the present disclosure, a separate mask may not be added when the plurality of second particles LSP2 is patterned so that the number of masks may be minimized or at least reduced, but is not limited thereto.

In the display device 700 according to still another exemplary embodiment of the present disclosure, the plurality of first particles LSP1 and the plurality of second particles LSP2 are disposed only in an area overlapping the active layer A so that out gassing by the plurality of first particles LSP1 and the plurality of second particles LSP2 may be minimized.

Specifically, the plurality of first particles LSP1 and the plurality of second particles LSP2 may be formed by the sol-gel method as an example. However, in the plurality of first particles LSP1 and the plurality of second particles LSP2 formed by the sol-gel method, for example, out gassing may be generated by a solvent which is not completely evaporated. Therefore, there may be a problem in that moisture permeates into components of the display device through a crack of the insulating layer generated by the out gassing. Accordingly, in the display device 700 according to still another exemplary embodiment of the present disclosure, the plurality of first particles LSP1 and the plurality of second particles LSP2 are disposed only in an area overlapping the active layer A. Therefore, out gassing by the plurality of first particles LSP1 and the plurality of second particles LSP2 may be minimized and the reliability of the display device 700 may be further improved.

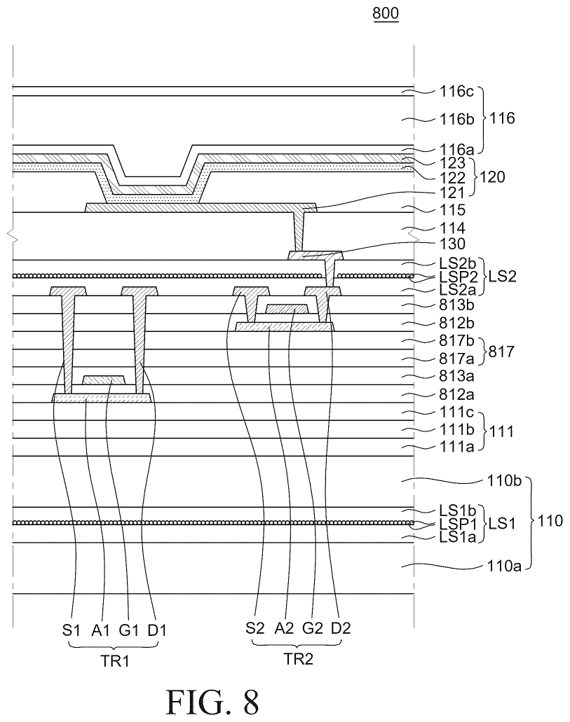

FIG. 8 is a cross-sectional view of a display device according to still another exemplary embodiment of the present disclosure. The only difference between a display device 800 of FIG. 8 and the display device 100 of FIGS. 1 to 3 is that a first transistor TR1 and a second transistor TR2 are disposed below the first light emitting diode 120, but the other configuration is the same so that a redundant description will be omitted.

Referring to FIG. 8, the display device 800 according to still another exemplary embodiment of the present disclosure includes a substrate 110, a first light shielding layer LS1, a lower buffer layer 111, a first transistor TR1, a first gate insulating layer 812a, a first interlayer insulating layer 813a, an upper buffer layer 817, a second transistor TR2, a second gate insulating layer 812b, a second interlayer insulating layer 813b, a second light shielding layer LS2, an auxiliary electrode 130, a planarization layer 114, a bank 115, a light emitting diode 120, and an encapsulation unit 116. The light emitting diode 120 may be electrically connected to the first transistor TR1 and the second transistor TR2.

The first transistor TR1 is disposed on the lower buffer layer 111. The first transistor TR1 may include a first active layer A1, a first gate electrode G1, a first source electrode S1, and a first drain electrode D1. However, depending on the design of the pixel circuit, the first source electrode S1 may serve as the first drain electrode and the first drain electrode D1 may serve as the first source electrode.

The first active layer A1 is disposed on the lower buffer layer 111. The first active layer A1 may include low temperature polycrystalline silicon (LTPS), such as amorphous silicon or polycrystalline silicon.

For example, the first active layer A1 may include a low-temperature polycrystalline silicon LTPS. For example, since the polysilicon material has a high mobility (100 cm2/Vs or higher), an energy power consumption is low and a reliability is high, so that the polysilicon material may be applied to a gate driver for a driving element which drives for a transistor for a light emitting diode and/or a multiplexer MUX. Therefore, in the display device 800 according to still another exemplary embodiment of the present disclosure, the first active layer A1 including low-temperature polysilicon LTPS may be applied as an active layer of the driving transistor, but is not limited thereto.

For example, the first active layer A1 may include a channel region in which a channel is formed when the first transistor TR1 is driven and a source region and a drain region on both sides of the channel region. The source region refers to a part of the first active layer A1 which is connected to the first source electrode S1 and the drain region refers to a part of the first active layer A1 which is connected to the first drain electrode D1. For example, the source region and the drain region may be configured by ion-doping (impurity doping) of the first active layer A1. The source region and the drain region may be generated by doping ions into the polycrystalline silicon material and the channel region may refer to a part in which the ions are not doped, but the polycrystalline silicon material remains.

A first gate insulating layer 812a may be disposed on the first active layer A1. The first gate insulating layer 812a may be configured by a single layer of silicon nitride (SiNx) or silicon oxide (SiOx) or a multi-layer thereof. In the first gate insulating layer 812a, a contact hole through which the first source electrode S1 and the first drain electrode D1 of the first transistor TR1 are connected to the source region and the drain region of the first active layer A1 of the first transistor TR1, respectively, may be formed.

The first gate electrode G1 of the first transistor TR1 is disposed on the first gate insulating layer 812a.

For example, the first gate electrode G1 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The first gate electrode G1 may be formed on the first gate insulating layer 812a so as to overlap the channel region of the first active layer A1 of the first transistor TR1.

The first interlayer insulating layer 813a may be disposed on the first gate insulating layer 812a and the first gate electrode G1. The first interlayer insulating layer 813a may be configured by a single layer of silicon nitride (SiNx) or silicon oxide (SiOx) or a multi-layer thereof.

The upper buffer layer 817 is disposed on the first interlayer insulating layer 813a. The upper buffer layer 817 may include a first upper buffer layer 817a and a second upper buffer layer 817b. The upper buffer layer 817 may be formed by a plurality of layers including the first upper buffer layer 817a and the second upper buffer layer 817b. Therefore, even though the upper buffer layer 817 may be referred to as a multi-buffer layer, the upper buffer layer 817 may be formed as a single layer or may be formed of a plurality of layers, other than two layers, but is not limited thereto.

For example, the first upper buffer layer 817a may be formed by a single layer of any one of amorphous silicon (a-Si), silicon nitride (SiNx), and silicon oxide (SiOx) or a plurality of layers thereof, but is not limited thereto.

For example, the second upper buffer layer 817b may be formed by a single layer of any one of amorphous silicon (a-Si), silicon nitride (SiNx), and silicon oxide (SiOx) or a plurality of layers thereof, but is not limited thereto.

The second transistor TR2 is disposed on the upper buffer layer 817. The second transistor TR2 may include a second active layer A2, a second gate electrode G2, a second source electrode S2, and a second drain electrode D2. However, depending on the design of the pixel circuit, the second source electrode S2 may serve as a second drain electrode and the second drain electrode D2 may serve as a second source electrode.

The second active layer A2 is disposed on the upper buffer layer 817. The second active layer A2 may include an oxide semiconductor material formed of metal oxide, such as indium-gallium-zinc-oxide (IGZO), indium-zinc-oxide (IZO), indium-gallium-tin-oxide (IGTO), or indium-gallium-oxide (IGO).

For example, the second active layer A2 may be formed of an oxide semiconductor. The oxide semiconductor material has a larger band gap as compared with a silicon material so that electrons may not jump over the band gap in an off state. Therefore, the oxide semiconductor material has a low off-current. Therefore, the transistor including an active layer which is formed of an oxide semiconductor is suitable for a switching transistor which maintains short on-time and long off-time, but is not limited thereto.

For example, the second active layer A2 may include a channel region in which a channel is formed when the second transistor TR2 is driven and a source region and a drain region on both sides of the channel region. The source region refers to a part of the second active layer A2 which is connected to the second source electrode S2 and the drain region refers to a part of the second active layer A2 which is connected to the second drain electrode D2. For example, the source region and the drain region may be configured by ion-doping (impurity doping) of the second active layer A2. The source region and the drain region may be generated by doping ions into the oxide semiconductor material and the channel region may refer to a part in which the ions are not doped, but the oxide semiconductor material remains.

The second gate insulating layer 812b may be disposed on the second active layer A2. The second gate insulating layer 812b may be configured as a single layer of silicon nitride (SiNx) or silicon oxide (SiOx) or a multi-layer thereof. In the second gate insulating layer 812b, a contact hole through which the second source electrode S2 and the second drain electrode D2 of the second transistor TR2 are connected to the source region and the drain region of the second active layer A2 of the second transistor TR2, respectively, may be formed.

The second gate electrode G2 of the second transistor TR2 is disposed on the second gate insulating layer 812b.

For example, the second gate electrode G2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. The second gate electrode G2 may be formed on the second gate insulating layer 812b so as to overlap the channel region of the second active layer A2 of the second transistor TR2.

The second interlayer insulating layer 813b may be disposed on the second gate insulating layer 812b and the second gate electrode G2. The second interlayer insulating layer 813b may be configured as a single layer of silicon nitride (SiNx) or silicon oxide (SiOx) or a multi-layer thereof.

The first source electrode S1, the first drain electrode D1, the second source electrode S2, and the second drain electrode D2 are disposed on the second interlayer insulating layer 813b.

The first source electrode S1 and the first drain electrode D1 may be electrically connected to the first active layer A1 of the first transistor TR1 through contact holes of the first gate insulating layer 812a, the first interlayer insulating layer 813a, the upper buffer layer 817, the second gate insulating layer 812b, and the second interlayer insulating layer 813b.

The second source electrode S2 and the second drain electrode D2 may be electrically connected to the second active layer A2 of the second transistor TR2 through contact holes of the second gate insulating layer 812b and the second interlayer insulating layer 813b.

The first source electrode S1, the first drain electrode D1, the second source electrode S2, and the second drain electrode D2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but are not limited thereto.

In the display device 800 according to still another exemplary embodiment of the present disclosure, the first light shielding layer LS1 is disposed below the first transistor TR1 and the second transistor TR2 and the second light shielding layer LS2 is disposed above the first transistor TR1 and the second transistor TR2. Therefore, light of various paths guided to the first transistor TR1 and the second transistor TR2 may be shielded.

Specifically, in the display device 800 according to still another exemplary embodiment of the present disclosure, the first light shielding layer LS1 is disposed between the first substrate 110a and the first transistor TR1 and the second light shielding layer LS2 is disposed between the second transistor TR2 and the light emitting diode 120. The first light shielding layer LS1 and the second light shielding layer LS2 may be disposed so as to correspond to the entire surface on the first substrate 110a. Each of the first light shielding layer LS1 and the second light shielding layer LS2 is configured to have a structure in which a plurality of particles LSP1 and LSP2 are disposed between first insulating layers LS1a and LS2a and second insulating layers LS1b and LS2b. At this time, the plurality of particles LSP1 and LSP2 are formed of a material having a refractive index higher than that of the first insulating layers LS1a and LS2a and the second insulating layers LS1b and LS2b to scatter or reflect light which is guided to the plurality of particles LSP1 and LSP2. Therefore, the first light shielding layer LS1 and the second light shielding layer LS2 may be configured to shield external light and internal light guided to the active layer A1 and A2 through various paths. Accordingly, in the display device 800 according to still another exemplary embodiment of the present disclosure, the first light shielding layer LS1 is disposed below the first transistor TR1 and the second transistor TR2 and the second light shielding layer LS2 is disposed above the first transistor TR1 and the second transistor TR2. Therefore, light of various paths guided to the first transistor TR1 and the second transistor TR2 may be shielded and the reliability of the first transistor TR1 and the second transistor TR2 may be improved.

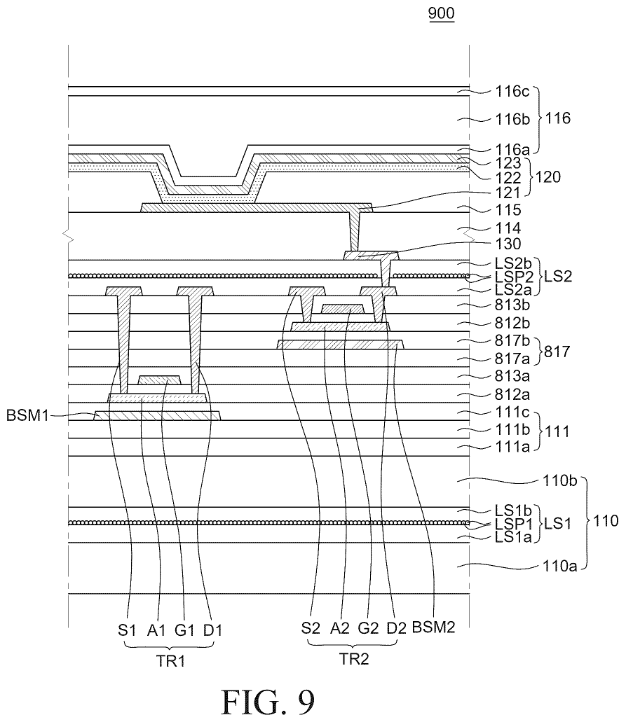

FIG. 9 is a cross-sectional view of a display device according to still another exemplary embodiment of the present disclosure. The only difference between a display device 900 of FIG. 9 and the display device 800 of FIG. 8 is that a protective layer BSM is further disposed, but the other configuration is the same, so that a redundant description will be omitted.

Referring to FIG. 9, a first protective layer BSM1 is disposed below the first active layer A1 to overlap the first active layer A1 and a second protective layer BSM2 is disposed below the second active layer A2 to overlap the second active layer A2. The first protective layer BSM1 is disposed between the first light shielding layer LS1 and the first active layer A1 of the first transistor TR1. The second protective layer BSM2 is disposed between the first light shielding layer LS1 and the second active layer A2 of the second transistor TR2. The first protective layer BSM1 is insulated from the first active layer A1 and the second protective layer BSM2 may be insulated from the second active layer A2. For example, the first protective layer BSM1 is disposed on the second lower buffer layer 111b and the third lower buffer layer 111c is disposed on the first protective layer BSM1 so that the first protective layer BSM1 may be insulated from the first active layer A1. Further, the second protective layer BSM2 is disposed on the first upper buffer layer 817a and the second upper buffer layer 817b is disposed on the second protective layer BSM2 to insulate the second protective layer BSM2 and the second active layer A2 from each other, but is not limited thereto.

The first protective layer BSM1 and the second protective layer BSM2 are formed of a metal material having low light transmittance and reflect light which is incident onto the first active layer A1 and the second active layer A2 from lower portions of the first active layer A1 and the second active layer A2. The first protective layer BSM1 and the second protective layer BSM2 shield light which is incident onto the first active layer A1 and the second active layer A2 and protect the first active layer A1 and the second active layer A2. For example, the first protective layer BSM1 and the second protective layer BSM2 may be referred to as bottom shield metals (BSM), but are not limited thereto. For example, the first protective layer BSM1 and the second protective layer BSM2 may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but are not limited thereto.

In the display device 900 according to still another exemplary embodiment of the present disclosure, the first protective layer BSM1 is disposed between the first light shielding layer LS1 and the first active layer A1 of the first transistor TR1 and the second protective layer BSM2 is disposed between the first light shielding layer LS1 and the second active layer A2 of the second transistor TR2. Therefore, the first protective layer BSM1 and the second protective layer BSM2 are configured to further shield external light and internal light of various paths guided to the first active layer A1 and the second active layer A2, together with the first light shielding layer LS1 and the second light shielding layer LS2. Accordingly, in the display device 900 according to still another exemplary embodiment of the present disclosure, the damage of the first active layer A1 and the second active layer A2 may be further minimized or at least reduced and the reliability of the first transistor TR1 and the second transistor TR2 may be further improved.

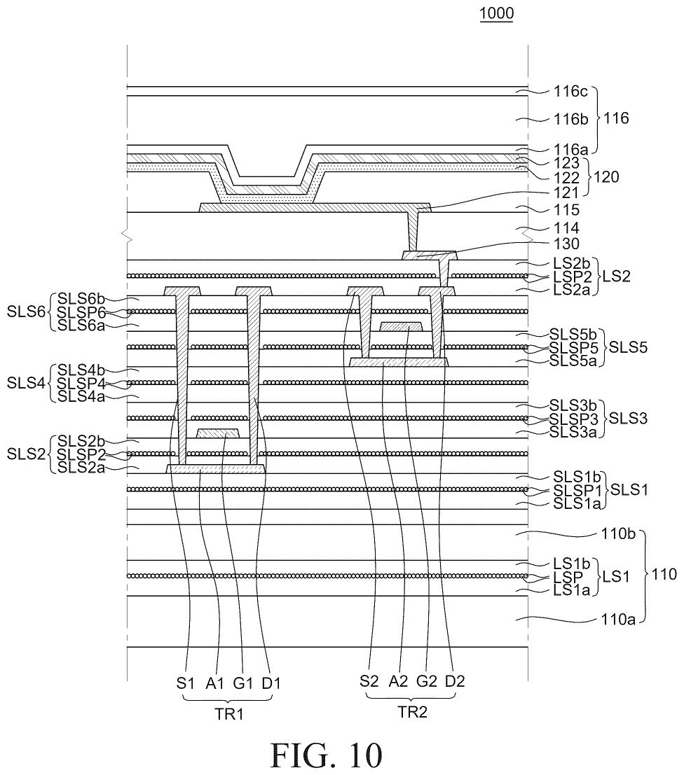

FIG. 10 is a cross-sectional view of a display device according to still another exemplary embodiment of the present disclosure. The only difference between a display device 1000 of FIG. 10 and the display device 800 of FIG. 8 is that a first sub light shielding layer SLS1, a second sub light shielding layer SLS2, a third sub light shielding layer SLS3, a fourth sub light shielding layer SLS4, a fifth sub light shielding layer SLS5, and a sixth sub light shielding layer SLS6 are further disposed, but the other configuration is the same, so that a redundant description will be omitted.

Referring to FIG. 10, the display device 1000 according to still another exemplary embodiment of the present disclosure further includes the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 disposed between the first light shielding layer LS1 and the second light shielding layer LS2.

The first sub light shielding layer SLS1 is disposed on the substrate 110. The first sub light shielding layer SLS1 is disposed between the substrate 110 and the first transistor TR1. The first sub light shielding layer SLS1 may be disposed between the second substrate 110b and the first active layer A1. The first sub light shielding layer SLS1 may be disposed so as to insulate a conductive component. For example, the first sub light shielding layer SLS1 may be disposed to insulate the substrate 110 and the first transistor TR1. Therefore, the first sub light shielding layer SLS1 may be referred to as a buffer layer, but is not limited thereto.

The first sub light shielding layer SLS1 includes a first insulating layer SLS1a, a plurality of first sub particles SLSP1, and a second insulating layer SLS1b.

The first insulating layer SLS1a may be disposed so as to correspond to the entire surface on the second substrate 110b. The first insulating layer SLS1a may be formed of an inorganic insulating material. For example, the first insulating layer SLS1a may be formed by a single layer of silicon nitride (SiNx) or silicon oxide (SiOx) or a multi-layer thereof, but is not limited thereto.

The plurality of first sub particles SLSP1 are disposed on the first insulating layer SLS1a. The plurality of first sub particles SLSP1 may be disposed between the first insulating layer SLS1a and the second insulating layer SLS1b. The plurality of first sub particles SLSP1 may be disposed at an interface of the first insulating layer SLS1a and the second insulating layer SLS1b. For example, the plurality of first sub particles SLSP1 are disposed on the first insulating layer SLS1a after forming the first insulating layer SLS1a and the second insulating layer SLS1b is disposed on the plurality of first sub particles SLSP1 so that the plurality of first sub particles are disposed between the first insulating layer SLS1a and the second insulating layer SLS1b. However, it is not limited thereto.

The plurality of first sub particles SLSP1 may be nano particles formed of a material including titanium (Ti). For example, the plurality of first sub particles SLSP1 may be particles having a size of nano-meters (nm) formed by a sol-gel method, but is not limited thereto.

The plurality of first sub particles SLSP1 may have a refractive index which is different from that of the first insulating layer SLS1a and the second insulating layer SLS1b. The plurality of first sub particles SLSP1 may have a refractive index larger than that of the first insulating layer SLS1a and the second insulating layer SLS1b. For example, when the first insulating layer SLS1a and the second insulating layer SLS1b are formed of silicon dioxide (SiO₂) having a refractive index of approximately 1.46, the plurality of first sub particles SLSP1 are formed of titanium dioxide (TiO2) having a refractive index of approximately 2.61, but is not limited thereto.

The second insulating layer SLS1b may be disposed on the plurality of first sub particles SLSP1 and the first insulating layer SLS1a exposed from the plurality of first sub particles SLSP1. The second insulating layer SLS1b may be formed of an inorganic insulating material. For example, the second insulating layer SLS1b may be formed by a single layer of silicon nitride (SiNx) or silicon oxide (SiOx) or a multi-layer thereof, but is not limited thereto.

The second sub light shielding layer SLS2 is disposed on the first sub light shielding layer SLS1 and the first active layer A1. The second sub light shielding layer SLS2 is disposed between the first active layer A1 and the first sub light shielding layer SLS1 and the first gate electrode G1 and the third sub light shielding layer SLS3. The second sub light shielding layer SLS2 may be disposed between the first active layer A1 and the first gate electrode G1. The second sub light shielding layer SLS2 may be disposed so as to insulate a conductive component. For example, the second sub light shielding layer SLS2 may be disposed so as to insulate the first active layer A1 and the first gate electrode G1. Therefore, the second sub light shielding layer SLS2 may be referred to as a first gate insulating layer, but is not limited thereto.

The second sub light shielding layer SLS2 includes a first insulating layer SLS2a, a plurality of second sub particles SLSP2, and a second insulating layer SLS2b.

The first insulating layer SLS2a is disposed on the first sub light shielding layer SLS1 and the first active layer A1. The first insulating layer SLS2a may be formed of an inorganic insulating material. For example, the first insulating layer SLS2a may be formed by a single layer of silicon nitride (SiNx) or silicon oxide (SiOx) or a multi-layer thereof, but is not limited thereto.

The plurality of second sub particles SLSP2 are disposed on the first insulating layer SLS2a. The plurality of second sub particles SLSP2 may be disposed between the first insulating layer SLS2a and the second insulating layer SLS2b. The plurality of second sub particles SLSP2 may be disposed at the interface of the first insulating layer SLS2a and the second insulating layer SLS2b. For example, the plurality of second sub particles SLSP2 are disposed on the first insulating layer SLS2a after forming the first insulating layer SLS2a and the second insulating layer SLS2b is disposed on the plurality of second sub particles SLSP2 so that the plurality of second sub particles are disposed between the first insulating layer SLS2a and the second insulating layer SLS2b. However, it is not limited thereto.

The plurality of second sub particles SLSP2 may be nano particles formed of a material including titanium (Ti). For example, the plurality of second sub particles SLSP2 may be particles having a size of nano-meters (nm) formed by a sol-gel method, but is not limited thereto.

The plurality of second sub particles SLSP2 may have a refractive index which is different from that of the first insulating layer SLS2a and the second insulating layer SLS2b. The plurality of second sub particles SLSP2 may have a refractive index larger than that of the first insulating layer SLS2a and the second insulating layer SLS2b. For example, when the first insulating layer SLS2a and the second insulating layer SLS2b are formed of silicon dioxide (SiO₂) having a refractive index of approximately 1.46, the plurality of second sub particles SLSP2 are formed of titanium dioxide (TiO2) having a refractive index of approximately 2.61, but is not limited thereto.

The second insulating layer SLS2b may be disposed on the plurality of second sub particles SLSP2 and the first insulating layer SLS2a exposed from the plurality of second sub particles SLSP2. The second insulating layer SLS2b may be formed of an inorganic insulating material. For example, the second insulating layer SLS2b may be formed by a single layer of silicon nitride (SiNx) or silicon oxide (SiOx) or a multi-layer thereof, but is not limited thereto.

The third sub light shielding layer SLS3 is disposed on the second sub light shielding layer SLS2 and the first gate electrode G1. The third sub light shielding layer SLS3 is disposed between the second sub light shielding layer SLS2 and the first gate electrode G1 and the fourth sub light shielding layer SLS4. The third sub light shielding layer SLS3 may be disposed so as to insulate a conductive component, but is not limited thereto.

The third sub light shielding layer SLS3 includes a first insulating layer SLS3a, a plurality of third sub particles SLSP3, and a second insulating layer SLS3b.

The first insulating layer SLS3a is disposed on the second sub light shielding layer SLS2 and the first gate electrode G1. The first insulating layer SLS3a may be formed of an inorganic insulating material. For example, the first insulating layer SLS3a may be formed by a single layer of silicon nitride (SiNx) or silicon oxide (SiOx) or a multi-layer thereof, but is not limited thereto.

The plurality of third sub particles SLSP3 are disposed on the first insulating layer SLS3a. The plurality of third sub particles SLSP3 may be disposed between the first insulating layer SLS3a and the second insulating layer SLS3b. The plurality of third sub particles SLSP3 may be disposed at an interface of the first insulating layer SLS3a and the second insulating layer SLS3b. For example, the plurality of third sub particles SLSP3 are disposed on the first insulating layer SLS3a after forming the first insulating layer SLS3a and the second insulating layer SLS3b is disposed on the plurality of third sub particles SLSP3 so that the plurality of third sub particles are disposed between the first insulating layer SLS3a and the second insulating layer SLS3b. However, it is not limited thereto.

The plurality of third sub particles SLSP3 may be nano particles formed of a material including titanium (Ti). For example, the plurality of third sub particles SLSP3 may be particles having a size of nano-meters (nm) formed by a sol-gel method, but is not limited thereto.

The plurality of third sub particles SLSP3 may have a refractive index which is different from that of the first insulating layer SLS3a and the second insulating layer SLS3b. The plurality of third sub particles SLSP3 may have a refractive index larger than that of the first insulating layer SLS3a and the second insulating layer SLS3b. For example, when the first insulating layer SLS3a and the second insulating layer SLS3b are formed of silicon dioxide (SiO₂) having a refractive index of approximately 1.46, the plurality of third sub particles SLSP3 are formed of titanium dioxide (TiO2) having a refractive index of approximately 2.61, but is not limited thereto.

The second insulating layer SLS3b may be disposed on the plurality of third sub particles SLSP3 and the first insulating layer SLS3a exposed from the plurality of third sub particles SLSP3. The second insulating layer SLS3b may be formed of an inorganic insulating material. For example, the second insulating layer SLS3b may be formed by a single layer of silicon nitride (SiNx) or silicon oxide (SiOx) or a multi-layer thereof, but is not limited thereto.

The fourth sub light shielding layer SLS4 is disposed on the third sub light shielding layer SLS3. The fourth sub light shielding layer SLS4 is disposed between the third sub light shielding layer SLS3 and the second transistor TR2. The fourth sub light shielding layer SLS4 may be disposed between the third sub light shielding layer SLS3 and the second active layer A2. The fourth sub light shielding layer SLS4 may be disposed so as to insulate a conductive component, but is not limited thereto.

The fourth sub light shielding layer SLS4 includes a first insulating layer SLS4a, a plurality of fourth sub particles SLSP4, and a second insulating layer SLS4b.

The first insulating layer SLS4a is disposed on the third sub light shielding layer SLS3. The first insulating layer SLS4a may be formed of an inorganic insulating material. For example, the first insulating layer SLS4a may be formed by a single layer of silicon nitride (SiNx) or silicon oxide (SiOx) or a multi-layer thereof, but is not limited thereto.

The plurality of fourth sub particles SLSP4 are disposed on the first insulating layer SLS4a. The plurality of fourth sub particles SLSP4 may be disposed between the first insulating layer SLS4a and the second insulating layer SLS4b. The plurality of fourth sub particles SLSP4 may be disposed at the interface of the first insulating layer SLS4a and the second insulating layer SLS4b. For example, the plurality of fourth sub particles SLSP4 are disposed on the first insulating layer SLS4a after forming the first insulating layer SLS4a and the second insulating layer SLS4b is disposed on the plurality of fourth sub particles SLSP4 so that the plurality of fourth sub particles are disposed between the first insulating layer SLS4a and the second insulating layer SLS4b. However, it is not limited thereto.

The plurality of fourth sub particles SLSP4 may be nano particles formed of a material including titanium (Ti). For example, the plurality of fourth sub particles SLSP4 may be particles having a size of nano-meters (nm) formed by a sol-gel method, but is not limited thereto.

The plurality of fourth sub particles SLSP4 may have a refractive index which is different from that of the first insulating layer SLS4a and the second insulating layer SLS4b. The plurality of fourth sub particles SLSP4 may have a refractive index larger than that of the first insulating layer SLS4a and the second insulating layer SLS4b. For example, when the first insulating layer SLS4a and the second insulating layer SLS4b are formed of silicon dioxide (SiO2) having a refractive index of approximately 1.46, the plurality of fourth sub particles SLSP4 is formed of titanium dioxide (TiO2) having a refractive index of approximately 2.61, but is not limited thereto.

The second insulating layer SLS4b may be disposed on the plurality of fourth sub particles SLSP4 and the first insulating layer SLS4a exposed from the plurality of fourth sub particles SLSP4. The second insulating layer SLS4b may be formed of an inorganic insulating material. For example, the second insulating layer SLS4b may be formed by a single layer of silicon nitride (SiNx) or silicon oxide (SiOx) or a multi-layer thereof, but is not limited thereto.

The fifth sub light shielding layer SLS5 is disposed on the fourth sub light shielding layer SLS4 and the second active layer A2. The fifth sub light shielding layer SLS5 is disposed between the second active layer A2 and the fourth sub light shielding layer SLS4 and the second gate electrode G2 and the sixth sub light shielding layer SLS6. The fifth sub light shielding layer SLS5 may be disposed between the second active layer A2 and the second gate electrode G2. The fifth sub light shielding layer SLS5 may be disposed so as to insulate a conductive component. For example, the fifth sub light shielding layer SLS5 may be disposed so as to insulate the second active layer A2 and the second gate electrode G2. Therefore, the fifth sub light shielding layer SLS5 may be referred to as a second gate insulating layer, but is not limited thereto.

The fifth sub light shielding layer SLS5 includes a first insulating layer SLS5a, a plurality of fifth sub particles SLSP5, and a second insulating layer SLS5b.

The first insulating layer SLS5a is disposed on the fourth sub light shielding layer SLS4 and the second active layer A2. The first insulating layer SLS5a may be formed of an inorganic insulating material. For example, the first insulating layer SLS5a may be formed by a single layer of silicon nitride (SiNx) or silicon oxide (SiOx) or a multi-layer thereof, but is not limited thereto.

The plurality of fifth sub particles SLSP5 are disposed on the first insulating layer SLS5a. The plurality of fifth sub particles SLSP5 may be disposed between the first insulating layer SLS5a and the second insulating layer SLS5b. The plurality of fifth sub particles SLSP5 may be disposed at the interface of the first insulating layer SLS5a and the second insulating layer SLS5b. For example, the plurality of fifth sub particles SLSP5 are disposed on the first insulating layer SLS5a after forming the first insulating layer SLS5a and the second insulating layer SLS5b is disposed on the plurality of fifth sub particles SLSP5 so that the plurality of fifth sub particles are disposed between the first insulating layer SLS5a and the second insulating layer SLS5b. However, it is not limited thereto.

The plurality of fifth sub particles SLSP5 may be nano particles formed of a material including titanium (Ti). For example, the plurality of fifth sub particles SLSP5 may be particles having a size of nano-meters (nm) formed by a sol-gel method, but is not limited thereto.

The plurality of fifth sub particles SLSP5 may have a refractive index which is different from that of the first insulating layer SLS5a and the second insulating layer SLS5b. The plurality of fifth sub particles SLSP5 may have a refractive index larger than that of the first insulating layer SLS5a and the second insulating layer SLS5b. For example, when the first insulating layer SLS5a and the second insulating layer SLS5b are formed of silicon dioxide (SiO2) having a refractive index of approximately 1.46, the plurality of fifth sub particles SLSP5 are formed of titanium dioxide (TiO2) having a refractive index of approximately 2.61, but is not limited thereto.

The second insulating layer SLS5b may be disposed on the plurality of fifth sub particles SLSP5 and the first insulating layer SLS5a exposed from the plurality of fifth sub particles SLSP5. The second insulating layer SLS5b may be formed of an inorganic insulating material. For example, the second insulating layer SLS5b may be formed by a single layer of silicon nitride (SiNx) or silicon oxide (SiOx) or a multi-layer thereof, but is not limited thereto.

The sixth sub light shielding layer SLS6 is disposed on the fifth sub light shielding layer SLS5 and the second gate electrode G2. The sixth sub light shielding layer SLS6 is disposed between the fifth sub light shielding layer SLS5 and the second gate electrode G2 and the second source electrode S2, the second drain electrode D2, and the second light shielding layer LS2. The sixth sub light shielding layer SLS6 may be disposed between the second gate electrode G2 and the second source electrode S2 and the second drain electrode D2. The sixth sub light shielding layer SLS6 may be disposed so as to insulate a conductive component. For example, the sixth sub light shielding layer SLS6 may be disposed so as to insulate the second gate electrode G2 and the second source electrode S2 and the second drain electrode D2. Therefore, the sixth sub light shielding layer SLS6 may be referred to as an upper interlayer insulating layer, but is not limited thereto.

The sixth sub light shielding layer SLS6 includes a first insulating layer SLS6a, a plurality of sixth sub particles SLSP6, and a second insulating layer SLS6b.

The first insulating layer SLS6a is disposed on the fifth sub light shielding layer SLS5 and the second gate electrode G2. The first insulating layer SLS6a may be formed of an inorganic insulating material. For example, the first insulating layer SLS6a may be formed by a single layer of silicon nitride (SiNx) or silicon oxide (SiOx) or a multi-layer thereof, but is not limited thereto.

The plurality of sixth sub particles SLSP6 are disposed on the first insulating layer SLS6a. The plurality of sixth sub particles SLSP6 may be disposed between the first insulating layer SLS6a and the second insulating layer SLS6b. The plurality of sixth sub particles SLSP6 may be disposed at the interface of the first insulating layer SLS6a and the second insulating layer SLS6b. For example, the plurality of sixth sub particles SLSP6 are disposed on the first insulating layer SLS6a after forming the first insulating layer SLS6a and the second insulating layer SLS6b is disposed on the plurality of sixth sub particles SLSP6 so that the plurality of sixth sub particles are disposed between the first insulating layer SLS6a and the second insulating layer SLS6b. However, it is not limited thereto.

The plurality of sixth sub particles SLSP6 may be nano particles formed of a material including titanium (Ti). For example, the plurality of sixth sub particles SLSP6 may be particles having a size of nano-meters (nm) formed by a sol-gel method, but is not limited thereto.

The plurality of sixth sub particles SLSP6 may have a refractive index which is different from that of the first insulating layer SLS6a and the second insulating layer SLS6b. The plurality of sixth sub particles SLSP6 may have a refractive index larger than that of the first insulating layer SLS6a and the second insulating layer SLS6b. For example, when the first insulating layer SLS6a and the second insulating layer SLS6b are formed of silicon dioxide (SiO2) having a refractive index of approximately 1.46, the plurality of sixth sub particles SLSP6 is formed of titanium dioxide (TiO2) having a refractive index of approximately 2.61, but is not limited thereto.

The second insulating layer SLS6b may be disposed on the plurality of sixth sub particles SLSP6 and the first insulating layer SLS6a exposed from the plurality of sixth sub particles SLSP6. The second insulating layer SLS6b may be formed of an inorganic insulating material. For example, the second insulating layer SLS6b may be formed by a single layer of silicon nitride (SiNx) or silicon oxide (SiOx) or a multi-layer thereof, but is not limited thereto.

In the meantime, in FIG. 10, it is illustrated that each of the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 includes the first insulating layer, the plurality of particles, and the second insulating layer. However, at least a part of the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 may include the first insulating layer, the plurality of particles, and the second insulating layer. Further, a part of the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 may not include the plurality of particles. However, the present disclosure is not limited thereto.

In the display device 1000 according to still another exemplary embodiment of the present disclosure, the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 are further disposed between the first light shielding layer LS1 and the second light shielding layer LS2. Therefore, the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 are configured to further shield external light and internal light of various paths guided to the first active layer A1 and the second active layer A2, together with the first light shielding layer LS1 and the second light shielding layer LS2. Accordingly, in the display device 1000 according to still another exemplary embodiment of the present disclosure, the damage of the first active layer A1 and the second active layer A2 may be further minimized and the reliability of the first transistor TR1 and the second transistor TR2 may be further improved.

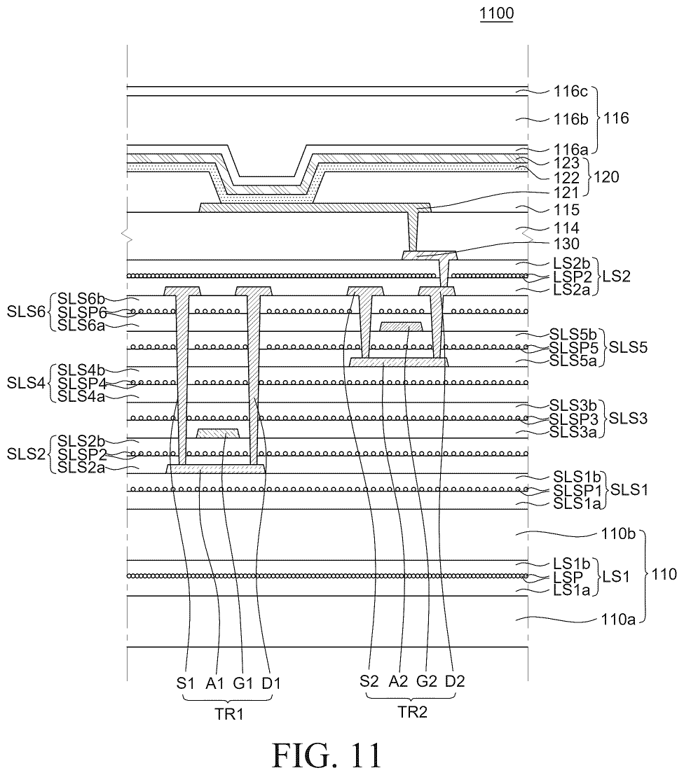

FIG. 11 is a cross-sectional view of a display device according to still another exemplary embodiment of the present disclosure. The only difference between a display device 1100 of FIG. 11 and the display device 1000 of FIG. 10 is a density of a plurality of particles SLSP disposed in a first sub light shielding layer SLS1, a second sub light shielding layer SLS2, a third sub light shielding layer SLS3, a fourth sub light shielding layer SLS4, a fifth sub light shielding layer SLS5, and a sixth sub light shielding layer SLS6, but the other configuration is the same, so that a redundant description will be omitted.

Referring to FIG. 11, the density of the plurality of sub particles SLSP1, SLSP2, SLSP3, SLSP4, SLSP5, and SLSP6 of the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 is lower than the density of the plurality of particles LSP1 and LSP2 of the first light shielding layer LS1 and the second light shielding layer LS2. The density of the plurality of sub particles SLSP1, SLSP2, SLSP3, SLSP4, SLSP5, and SLSP6 included in the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6, respectively, is lower than the density of the plurality of particles LSP1 and LSP2 included in the first light shielding layer LS1 and the second light shielding layer LS2, respectively. The densities of the plurality of first sub particles SLSP1, the plurality of second sub particles SLSP2, the plurality of third sub particles SLSP3, the plurality of fourth sub particles SLSP4, the plurality of fifth sub particles SLSP5, and the plurality of sixth sub particles SLSP6 included in the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6, respectively, are lower than the densities of the plurality of first particles LSP1 and the plurality of second particles LSP2 included in the first light shielding layer LS1 and the second light shielding layer LS2, respectively. An amount of the plurality of sub particles SLSP1, SLSP2, SLSP3, SLSP4, SLSP5, and SLSP6 formed by the sol-gel method is adjusted by changing an amount of precursors used when the plurality of sub particles SLSP1, SLSP2, SLSP3, SLSP4, SLSP5, and SLSP6 are formed using the sol-gel method as an example to control the density of the plurality of sub particles SLSP1, SLSP2, SLSP3, SLSP4, SLSP5, and SLSP6. However, the present disclosure is not limited thereto.

In the display device 1100 according to still another exemplary embodiment of the present disclosure, the density of the plurality of sub particles SLSP1, SLSP2, SLSP3, SLSP4, SLSP5, and SLSP6 of the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 is configured to be lower than the density of the plurality of particles LSP1 and LSP2 of the first light shielding layer LS1 and the second light shielding layer LS2 to minimize out gassing for the peripheral portion of the transistor.

Specifically, the plurality of particles LSP1 and LSP2 and the plurality of sub particles SLSP1, SLSP2, SLSP3, SLSP4, SLSP5, and SLSP6 are formed by the sol-gel method as an example. However, in the plurality of particles LSP1 and LSP2 and the plurality of sub particles SLSP1, SLSP2, SLSP3, SLSP4, SLSP5, and SLSP6 formed by the sol-gel method, for example, out gassing may be generated by a solvent which is not completely evaporated. At this time, various components, such as an active layer, which is specifically vulnerable to moisture permeation, are disposed on the transistor. Therefore, when out gassing is generated from the insulating layer disposed in the periphery of the transistor, there is a problem in that moisture permeates into components of the transistor through a crack of the insulating layer generated by the out gassing. Accordingly, in the display device 1100 according to still another exemplary embodiment of the present disclosure, the density of the plurality of sub particles SLSP1, SLSP2, SLSP3, SLSP4, SLSP5, and SLSP6 of the first sub light shielding layer SLS1, the second sub light shielding layer SLS2, the third sub light shielding layer SLS3, the fourth sub light shielding layer SLS4, the fifth sub light shielding layer SLS5, and the sixth sub light shielding layer SLS6 which are disposed in the peripheral portion of the first transistor TR1 and the second transistor TR2 is configured to be lower than the density of the plurality of particles LSP1 and LSP2 of the first light shielding layer LS1 and the second light shielding layer LS2 to minimize out gassing for the peripheral portion of the transistor. Further, the reliability of the first transistor TR1 and the second transistor TR2 may be further improved.

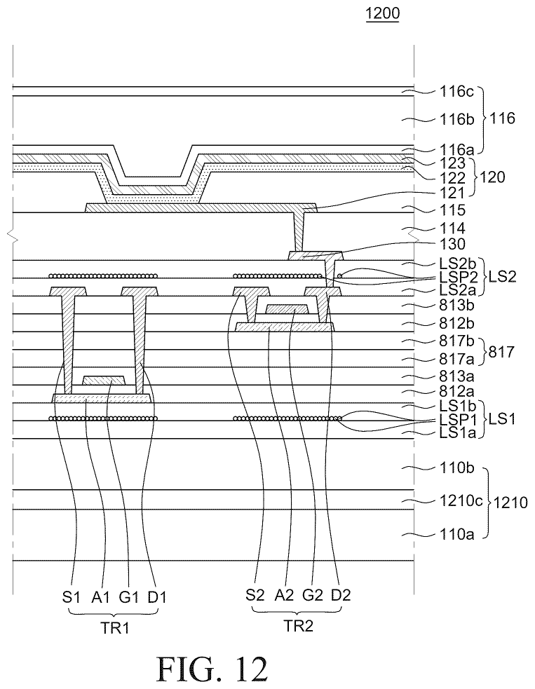

FIG. 12 is a cross-sectional view of a display device according to still another exemplary embodiment of the present disclosure. The only difference between the display device 1200 of FIG. 12 and the display device 800 of FIG. 8 is that a first light shielding layer LS1 and a second light shielding layer LS2 are disposed only in an area overlapping a first active layer A1 and a second active layer A2, but the other configuration is substantially the same, so that a redundant description will be omitted.

Referring to FIG. 12, a substrate 1210 includes a first substrate 110a, an inorganic insulating layer 1210c, and a second substrate 110b. The inorganic insulating layer 1210c may be disposed between the first substrate 110a and the second substrate 110b. As described above, the substrate 1210 is configured by a triple layer of the first substrate 110a, the inorganic insulating layer 1210c, and the second substrate 110b to minimize or at least reduce the moisture permeation from the outside.

The inorganic insulating layer 1210c is disposed on the entire surface on the first substrate 110a. The inorganic insulating layer 1210c may be formed of an inorganic insulating material. For example, the inorganic insulating layer 1210c may be formed by a single layer of silicon nitride (SiNx) or silicon oxide (SiOx) or a multi-layer thereof, but is not limited thereto.

Referring to FIG. 12, the first light shielding layer LS1 is disposed on the substrate 1210. The plurality of first particles LSP1 of the first light shielding layer LS1 are disposed only in an area overlapping the first active layer A1 and the second active layer A2. For example, the plurality of first particles LSP1 are patterned by processes of patterning a photoresist using a mask, coating and drying a material for forming the plurality of first particles LSP1, and then removing a photoresist to be disposed only in the area overlapping the first active layer A1 and the second active layer A2, but is not limited thereto.

Referring to FIG. 12, the second light shielding layer LS2 is disposed on the second interlayer insulating layer 813b. The plurality of second particles LSP2 of the second light shielding layer LS2 are disposed only in an area overlapping the first active layer A1 and the second active layer A2. For example, the plurality of second particles LSP2 are patterned by processes of patterning a photoresist using a mask, coating and drying a material for forming the plurality of second particles LSP2, and then removing a photoresist to be disposed only in the area overlapping the first active layer A1 and the second active layer A2, but is not limited thereto.

In the display device 1200 according to still another exemplary embodiment of the present disclosure, the plurality of first particles LSP1 and the plurality of second particles LSP2 are disposed only in an area overlapping the first active layer A1 and the second active layer A2 so that out gassing by the plurality of first particles LSP1 and the plurality of second particles LSP2 may be minimized.

Specifically, the plurality of first particles LSP1 and the plurality of second particles LSP2 may be formed by the sol-gel method as an example. However, in the plurality of first particles LSP1 and the plurality of second particles LSP2 formed by the sol-gel method, for example, out gassing may be generated by a solvent which is not completely evaporated. Therefore, there may be a problem in that moisture permeates into components of the display device through a crack of the insulating layer generated by the out gassing. Accordingly, in the display device 1200 according to still another exemplary embodiment of the present disclosure, the plurality of first particles LSP1 and the plurality of second particles LSP2 are disposed only in an area overlapping the first active layer A1 and the second active layer A2 so that out gassing by the plurality of first particles LSP1 and the plurality of second particles LSP2 may be minimized or at least reduced. Further, the reliability of the display device 1200 may be further improved.

The exemplary embodiments of the present disclosure can also be described as follows:

According to an aspect of the present disclosure, a display device includes a first substrate; a first light shielding layer disposed on the first substrate; a transistor disposed on the first light shielding layer; a second light shielding layer disposed on the transistor; and a light emitting diode which is disposed on the second light shielding layer and is electrically connected to the transistor, and each of the first light shielding layer and the second light shielding layer includes a first insulating layer; a plurality of particles disposed on the first insulating layer; and a second insulating layer disposed on the first insulating layer and the plurality of particles.

The plurality of particles may have a refractive index which is different from that of the first insulating layer and the second insulating layer.

The plurality of particles may have a refractive index which is larger than that of the first insulating layer and the second insulating layer.

The plurality of particles may include titanium (Ti).

The first insulating layer and the second insulating layer may be inorganic insulating layers.

The transistor may include an active layer, a gate electrode, a source electrode, and a drain electrode.

The display device may further comprise a protective layer disposed between the first light shielding layer and the transistor so as to overlap the active layer.

The transistor may include an active layer, a gate electrode, a source electrode, and a drain electrode and the plurality of particles of the first light shielding layer and the plurality of particles of the second light shielding layer may be disposed only in an area overlapping the active layer.

The display device may further comprise a plurality of sub light shielding layers disposed between the first light shielding layer and the second light shielding layer.

At least a part of the plurality of sub light shielding layers may include a first insulating layer; a plurality of particles disposed on the first insulating layer of the sub light shielding layer; and a second insulating layer disposed on the first insulating layer and the plurality of particles of the sub light shielding layer.

The plurality of particles of the plurality of sub light shielding layers may have a refractive index which is larger than that of the first insulating layer and the second insulating layer of the sub light shielding layer.

The plurality of sub light shielding layers may be disposed between the first light shielding layer and the second light shielding layer to insulate a conductive component.

A density of the plurality of particles of the first light shielding layer and the second light shielding layer may be higher than a density of the plurality of particles of the plurality of sub light shielding layers.

The display device may further comprise a second substrate disposed between the first light shielding layer and the transistor.

According to another aspect of the present disclosure, a display device includes a first substrate; a first light shielding layer disposed on the first substrate; a first transistor which is disposed on the first light shielding layer and includes a first active layer, a first gate electrode, a first source electrode, and a first drain electrode; a second transistor which is disposed on the first transistor and includes a second active layer, a second gate electrode, a second source electrode, and a second drain electrode; and a light emitting diode which is disposed above the second transistor and is electrically connected to the first transistor and the second transistor.

The second active layer may be formed of oxide semiconductor.

The first light shielding layer may include a first insulating layer; a plurality of particles disposed on the first insulating layer; and a second insulating layer disposed on the first insulating layer and the plurality of particles.

The plurality of particles may have a refractive index which is different from that of the first insulating layer and the second insulating layer.

The plurality of particles may have a refractive index which is larger than that of the first insulating layer and the second insulating layer.

The plurality of particles may include titanium (Ti).

The first insulating layer and the second insulating layer may be inorganic insulating layers.

The display device may further comprise a first protective layer which is disposed so as to overlap the first active layer below the first active layer; and a second protective layer which is disposed so as to overlap the second active layer below the second active layer.

The display device may further comprise a second light shielding layer disposed on the second transistor.

The second light shielding layer may include a first insulating layer; a plurality of particles disposed on the first insulating layer of the second light shielding layer; and a second insulating layer disposed on the first insulating layer and the plurality of particles of the second light shielding layer.

The plurality of particles of the second light shielding layer may have a refractive index which is different from that of the first insulating layer and the second insulating layer of the second light shielding layer.

The plurality of particles of the first light shielding layer and the plurality of particles of the second light shielding layer may be disposed only in an area overlapping the first active layer and the second active layer.

The display device may further comprise a plurality of sub light shielding layers disposed between the first light shielding layer and the second light shielding layer.

At least a part of the plurality of sub light shielding layers may include a first insulating layer; a plurality of particles disposed on the first insulating layer of the sub light shielding layer; and a second insulating layer disposed on the first insulating layer and the plurality of particles of the sub light shielding layer.

The plurality of particles of the plurality of sub light shielding layers may have a refractive index which is larger than that of the first insulating layer and the second insulating layer of the sub light shielding layer.

The plurality of sub light shielding layers may be disposed between the first light shielding layer and the second light shielding layer to insulate a conductive component.

A density of the plurality of particles of the first light shielding layer and the second light shielding layer may be higher than a density of the plurality of particles of the plurality of sub light shielding layers.

The display device may further comprise a second substrate disposed between the first light shielding layer and the first transistor.

The first active layer may be formed of low temperature polycrystalline silicon (LTPS).

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate;
a first light shielding layer on the first substrate;
a transistor on the first light shielding layer;
a second light shielding layer on the transistor; and
a light emitting diode on the second light shielding layer and is electrically connected to the transistor,
wherein each of the first light shielding layer and the second light shielding layer includes:
a first insulating layer;
a plurality of particles on the first insulating layer; and
a second insulating layer on the first insulating layer and the plurality of particles.

2. The display device according to claim 1, wherein the plurality of particles have a refractive index that is different from that of a refractive index of the first insulating layer and a refractive index of the second insulating layer.

3. The display device according to claim 2, wherein the plurality of particles have a refractive index that is larger than the refractive index of the first insulating layer and the refractive index of the second insulating layer.

4. The display device according to claim 2, wherein the plurality of particles include titanium (Ti).

5. The display device according to claim 1, wherein the first insulating layer and the second insulating layer are inorganic insulating layers.

6. The display device according to claim 1, wherein the transistor includes an active layer, a gate electrode, a source electrode, and a drain electrode, and the display device further comprises:
a protective layer between the first light shielding layer and the transistor, the protective layer overlapping the active layer.

7. The display device according to claim 1, wherein the transistor includes an active layer, a gate electrode, a source electrode, and a drain electrode and the plurality of particles of the first light shielding layer and the plurality of particles of the second light shielding layer are only in an area overlapping the active layer.

8. The display device according to claim 1, further comprising:
a plurality of sub light shielding layers between the first light shielding layer and the second light shielding layer, wherein at least a part of the plurality of sub light shielding layers includes:
a first insulating layer;
a plurality of particles on the first insulating layer of the sub light shielding layer; and
a second insulating layer on the first insulating layer and the plurality of particles of the sub light shielding layer, and
wherein the plurality of particles of the plurality of sub light shielding layers have a refractive index that is larger than a refractive index of the first insulating layer and the refractive index of the second insulating layer of the sub light shielding layer.

9. The display device according to claim 8, wherein the plurality of sub light shielding layers are between the first light shielding layer and the second light shielding layer and insulate a conductive component.

10. The display device according to claim 8, wherein a density of the plurality of particles of the first light shielding layer and the second light shielding layer is higher than a density of the plurality of particles of the plurality of sub light shielding layers.

11. The display device according to claim 1, further comprising:
a second substrate between the first light shielding layer and the transistor.

12. The display device according to claim 1, wherein the first light shielding layer and the second light shielding layer are disposed so as to correspond to an entire surface on the first substrate.

13. The display device according to claim 1, further comprising:
an encapsulation layer on the light emitting diode, the encapsulation layer including:
a first encapsulation layer including an inorganic material;
a second encapsulation layer on the first encapsulation layer, the second encapsulation layer including an organic material; and
a third encapsulation layer on the second encapsulation layer, the third encapsulation layer including an inorganic material,
wherein the second encapsulation layer has a smaller area than that of the first encapsulation layer.

14. The display device according to claim 6, further comprising:
a lower buffer layer on the protective layer and insulating the protective layer from the active layer.

15. The display device according to claim 7, wherein the plurality of particles of the first light shielding layer and the plurality of particles of the second light shielding layer are disposed with a same pattern as the active layer.

16. A display device, comprising:
a first substrate;
a first light shielding layer on the first substrate;
a first transistor on the first light shielding layer and includes a first active layer, a first gate electrode, a first source electrode, and a first drain electrode;
a second transistor on the first transistor and includes a second active layer, a second gate electrode, a second source electrode, and a second drain electrode; and
a light emitting diode which is disposed above the second transistor and is electrically connected to the first transistor and the second transistor,
wherein the second active layer includes an oxide semiconductor, and
the first light shielding layer includes:
a first insulating layer;
a plurality of particles on the first insulating layer; and
a second insulating layer on the first insulating layer and the plurality of particles.

17. The display device according to claim 16, wherein the plurality of particles have a refractive index that is different from a refractive index of the first insulating layer and a refractive index of the second insulating layer.

18. The display device according to claim 17, wherein the plurality of particles have a refractive index that is larger than the refractive index of the first insulating layer and the refractive index of the second insulating layer.

19. The display device according to claim 17, wherein the plurality of particles include titanium.

20. The display device according to claim 16, wherein the first insulating layer and the second insulating layer are inorganic insulating layers.

21. The display device according to claim 16, further comprising:
a first protective layer that overlaps the first active layer below the first active layer; and
a second protective layer that overlaps the second active layer below the second active layer.

22. The display device according to claim 16, further comprising:
a second light shielding layer on the second transistor, the second light shielding layer including:
a first insulating layer;
a plurality of particles on the first insulating layer of the second light shielding layer; and
a second insulating layer on the first insulating layer and the plurality of particles of the second light shielding layer, and
wherein the plurality of particles of the second light shielding layer have a refractive index that is different from a refractive index of the first insulating layer and a refractive index of the second insulating layer of the second light shielding layer.

23. The display device according to claim 22, wherein the plurality of particles of the first light shielding layer and the plurality of particles of the second light shielding layer are only in an area overlapping the first active layer and the second active layer.

24. The display device according to claim 22, further comprising:
a plurality of sub light shielding layers between the first light shielding layer and the second light shielding layer,
wherein at least a part of the plurality of sub light shielding layers includes:
a first insulating layer;
a plurality of particles on the first insulating layer of the sub light shielding layer; and
a second insulating layer on the first insulating layer and the plurality of particles of the sub light shielding layer, and
wherein the plurality of particles of the plurality of sub light shielding layers have a refractive index that is larger than a refractive index of the first insulating layer and a refractive index of the second insulating layer of the sub light shielding layer.

25. The display device according to claim 24, wherein the plurality of sub light shielding layers are between the first light shielding layer and the second light shielding layer and insulate a conductive component.

26. The display device according to claim 25, wherein a density of the plurality of particles of the first light shielding layer and the second light shielding layer is higher than a density of the plurality of particles of the plurality of sub light shielding layers.

27. The display device according to claim 16, further comprising:
a second substrate between the first light shielding layer and the first transistor.

28. The display device according to claim 16, wherein the first active layer is formed of low temperature polycrystalline silicon.

29. The display device according to claim 22, wherein the first light shielding layer and the second light shielding layer are disposed so as to correspond to an entire surface on the first substrate.

30. The display device according to claim 16, further comprising:
an encapsulation layer on the light emitting diode, the encapsulation layer including:
a first encapsulation layer including an inorganic material;
a second encapsulation layer on the first encapsulation layer, the second encapsulation layer including an organic material; and
a third encapsulation layer on the second encapsulation layer, the third encapsulation layer including an inorganic material,
wherein the second encapsulation layer has a smaller area than that of the first encapsulation layer.

31. The display device according to claim 21, further comprising:
a lower buffer layer on the first protective layer and insulates the first protective layer from the first active layer and an upper buffer layer on the second protective layer and insulate the second protective layer and the second active layer.

32. The display device according to claim 22, wherein the plurality of particles of the first light shielding layer and the plurality of particles of the second light shielding layer are disposed with a same pattern as the first active layer and the second active layer.
